(19) United States
(12) Patent Application Publication
(10) Pub. No.: US 2024/0413610 A1
(43) Pub. Date: Dec. 12, 2024

(54) METHODS FOR FABRICATING A VERTICAL CAVITY SURFACE EMITTING LASER

(71) Applicant: The Regents of the University of California, Oakland, CA (US)

(72) Inventors: Srinivas Gandrothula, Ibaraki (JP); Shuji Nakamura, Santa Barbara, CA (US); Steven P. DenBaars, Goleta, CA (US)

(73) Assignee: The Regents of the University of California, Oakland, CA (US)

(21) Appl. No.: 18/699,439

(22) PCT Filed: Oct. 24, 2022
(86) PCT No.: PCT/US22/47534

§ 371 Date: Apr. 8, 2024

Related U.S. Application Data
(60) Provisional application No. 63/270,618, filed on Oct. 22, 2021.

(51) Int. Cl. H01S 5/183; H01S 5/02; H01S 5/30

(52) U.S. Cl. CPC H01S 5/18361; H01S 5/0217; H01S 5/3013; H01S 2304/12

(57) ABSTRACT

Methods for fabricating a vertical cavity surface emitting laser (VCSEL) using epitaxial lateral overgrowth (ELO). The ELO layers comprise island-like III-nitride semiconductor layers grown on a substrate using a growth restrict mask, wherein the island-like III-nitride semiconductor layers comprise a light emitting resonant cavity. An aperture for the resonant cavity is fabricated on a wing of the ELO layers with distributed Bragg reflector (DBR) mirrors formed on bottom and top regions of the wing of the ELO layers.

### CROSS REFERENCE TO RELATED APPLICATIONS

This application claims the benefit under 35 U.S.C. Section 119 (e) of the following co-pending and commonly-assigned application:
U.S. Provisional Application Ser. No. 63/270,618, filed on Oct. 22, 2021, by Srinivas Gandrothula, Shuji Nakamura, and Steven P. DenBaars, entitled “VERTICAL CAVITY SURFACE EMITTING LASER FABRICATION METHOD,” Attorney's Docket Number G&C 30794.0810USP1 (UC 2022-768-1); which application is incorporated by reference herein.

This application is related to the following co-pending and commonly-assigned applications:
U.S. Utility patent application Ser. No. 17/766,960, filed on Apr. 6, 2022, by Srinivas Gandrothula, Takeshi Kamikawa and Masahiro Araki, entitled “METHOD OF FABRICATING A RESONANT CAVITY AND DISTRIBUTED BRAGG REFLECTOR MIRRORS FOR A VERTICAL CAVITY SURFACE EMITTING LASER ON A WING OF AN EPITAXIAL LATERAL OVERGROWTH REGION,” attorney's docket number 30794.06745USWO (UC 2020-071-2), which application claims the benefit under 35 U.S.C. Section 365 (c) of co-pending and commonly-assigned PCT International Patent Application No. PCT/US20/57026, filed on Oct. 23, 2020, by Srinivas Gandrothula, Takeshi Kamikawa and Masahiro Araki, entitled “METHOD OF FABRICATING A RESONANT CAVITY AND DISTRIBUTED BRAGG REFLECTOR MIRRORS FOR A VERTICAL CAVITY SURFACE EMITTING LASER ON A WING OF AN EPITAXIAL LATERAL OVERGROWTH REGION,” attorney's docket number 30794.0745WOU1 (UC 2020-071-2), which application claims the benefit under 35 U.S.C. Section 119 (e) of co-pending and commonly-assigned U.S. Provisional Application Ser. No. 62/924,756, filed on Oct. 23, 2019, by Srinivas Gandrothula, Takeshi Kamikawa and Masahiro Araki, entitled “METHOD OF FABRICATING A RESONANT CAVITY AND DISTRIBUTED BRAGG REFLECTOR MIRRORS FOR A VERTICAL CAVITY SURFACE EMITTING LASER ON A WING OF AN EPITAXIAL LATERAL OVERGROWTH REGION,” attorneys' docket number G&C 30794.0745USP1 (UC 2020-071-1);
all of which applications are incorporated by reference herein.

### BACKGROUND OF THE INVENTION

### 1. Field of the Invention

This invention is related to the fabrication of vertical cavity surface emitting lasers (VCSELs) using an epitaxial lateral overgrowth (ELO) technique on foreign substrates.

### 2. Background

Since the first demonstration of (Al, In, Ga)N-based blue VCSELs in 2008, the maximum output power and threshold current density has been improved significantly after a decade of technology advancements. The key challenges for the realization of III-nitride VCSELs mass production are the difficulties in fabricating distributed Bragg's reflectors (DBRs) for a resonant cavity. The significant tensile strain between AlN and GaN hampered an intuitive cavity design with two epitaxial DBRs from arsenide based VCSELs. Therefore, many alternative cavity structures and processing technologies were developed; for example, lattice-matched AlInN/GaN DBRs, nano-porous DBRs, or double dielectric DBRs via various overgrowth or film transfer processing strategies. The VCSELs reported in the literature have shortcomings either in terms of yield or complex manufacturing procedures.

Thus, there is a need in the art for improved methods for fabricating VCSELs. The present invention satisfies that need.

### SUMMARY OF THE INVENTION

This invention solves the problems mentioned above using hetero-epitaxy and substrate removal. GaN-on-Si or GaN-on-Sapphire templates can be used to grow reduced threading dislocation III-nitride epitaxial layers by selectively masking and exposing very little of the high defects contained by a Ga(Al)N template layer. The resulting high crystalline quality layers can be grown on the masked portions. Then, a conventional VCSEL device fabrication can be adopted on the high crystalline quality layers. The problematic n-side DBR can be solved by removing the host substrate and only utilizing layers grown over the masked portion.

In the case of GaN-on-Si, the p-side of the device layers with an epitaxial or dielectric DBR is attached to a submount and then a chemical etchant may be used to lift-off the device layers from the host Si substrate. The interface roughness of ELO III-nitride layers on a wing of a growth restrict mask, also referred to as an ELO mask, can be controlled to a sub-nanometer level, and thus an external DBR, either epitaxial or dielectric, can be attached to complete the final device. Alternatively, one can form a curved surface on the lift-off layer to form a curved DBR mirror to minimize electromagnetic field loss and to refocus the field back into the gain region of the device.

Similarly, in the case of GaN-on-Sapphire, laser lift-off (LLO) can be used to remove the device layers from the host Sapphire substrate. In this particular approach, LLO is used at an open window region of a wing of the ELO III-nitride layers, so that subsequent III-nitride device layers grown on the ELO III-nitride layers will not be damaged. Alternatively, the whole device can be exposed to the laser without damaging the device as a back portion of the device is protected from the laser's exposure by the growth restrict mask. However, it is preferred to expose only an open window region to the laser.

Key aspects of this invention include the following:
A light emitting aperture of the device is made on a wing region of the ELO III-nitride layers; therefore, the device aperture is intended to have a better crystal quality in terms of defects and stacking faults than a device aperture made directly on a host substrate.
At least one of the DBR mirrors of the cavity is placed on a wing of the ELO III-nitride layers, and a DBR mirror may be placed at a backside of the ELO III-nitride layers after separating the ELO III-nitride layers from the host substrate.
The substrate can be removed by chemical etching in the case of GaN-on-Si, or using LLO for a GaN-on-Sapphire template, or by peeling using a cryogenic treatment.
This method is independent of crystal orientations of the substrate.
In this invention, preparing a surface for DBR mirrors for resonant cavity VCSELs uses only an ELO mask.
This invention can be applied to make a curved mirror when a long resonant cavity for the VCSEL is desired.
This invention includes a method for realizing stress relaxation of the ELO III-nitride layers, which results in crack-free and long-lived devices, by placing one of the DBR mirrors after removing the ELO III-nitride layers from the host substrate.
In this invention, discrete layers of GaN ELO are preferred to avoid cracking and also to provide an easy method for removing the growth restrict mask.

A few of the possible designs using this method are illustrated in the following description. The invention has many benefits as compared to conventionally manufacturable device elements when combined with the cross-referenced inventions on removing semiconducting devices from a semiconducting substrate set forth above.

Moreover, to overcome the limitations in the prior art described above, and to overcome other limitations that will become apparent upon reading and understanding this specification, the present invention discloses a method for fabricating a good quality aperture for devices that emit light normal to substrates from where the devices have been epitaxially fabricated, such as VCSELs.

Specifically, this invention performs the following steps: island-like III-nitride semiconductor layers are grown on a substrate using a growth restrict mask and an ELO method, wherein the growth restrict mask occupies at least 50% or more of a single device. The ELO regions are meant to be a wing of the ELO III-nitride layers with reduced dislocation densities as compared to a region that is not covered by the wing of the ELO III-nitride layers. The current confining aperture of the VCSEL is confined to the ELO region, such that a good crystal quality is guaranteed. The resonant cavity and DBR mirrors of the VCSEL device are made on the ELO regions, and on the top and bottom of the ELO regions, respectively.

The interface between the growth restrict mask and the ELO regions is smooth enough to fabricate one of the light-reflecting DBR mirrors. The ELO III-nitride layers and the subsequent III-nitride device layers grown on the ELO III-nitride layers together comprise island-like III-nitride semiconductor layers that are removed from the substrate and a DBR mirror is placed at the backside of the ELO III-nitride layers, which is the interface between the growth restrict mask and the ELO III-nitride layers, wherein the substrate removal in this particular application is simple as foreign substrates, such as (Al) GaN-on-Si or (Al) GaN-on-Sapphire, etc., are used.

The ELO method to form the island-like III-nitride semiconductor layers may include growth by metal organic chemical vapor deposition (MOCVD), hydride vapor phase epitaxy (HVPE), etc., to accurately control thickness, and thus the cavity length of the VCSEL device. The III-nitride semiconductor layers are dimensioned to create one or more of the island-like III-nitride semiconductor layers. Alternatively, the ELO III-nitride layers can made to coalesce initially, such that they can be later divided into individual devices.

Every device made on an ELO wing can be addressed separately or together with other devices, by designing a proper fabrication process. For example, one could make a common cathode or anode for a pair of devices around an open window region in the ELO III-nitride layers. Such a process simplifies monolithic integration or addressing individual devices. Consequently, a high yield can be obtained.

Alternatively, one may also use one of the wings for placement of an aperture and for placement of electrical pads.

Moreover, the present invention can use hetero-substrates to grow the island-like III-nitride semiconductor layers that form the bar. For example, a GaN template grown on a hetero-substrate, such as Sapphire, Si, SiC, SiN, GaAs, Ga₂O₃, LiAlO₂, etc., can be used in the present invention.

Furthermore, the ELO method can drastically reduce dislocation density and stacking faults density when non-Basel GaN crystal planes are used, which are critical issues when using hetero-substrates.

Therefore, this invention can solve many kinds of problems incurred with the use of hetero-substrates, at the same time. For example, in a laser device, the interface between growth restrict mask and the ELO III-nitride layer can be used as a facet for the resonator.

### BRIEF DESCRIPTION OF THE DRAWINGS

Referring now to the drawings in which like reference numbers represent corresponding parts throughout:

FIGS. 1(a), 1(b), 1(c) and 1(d) are schematics, wherein: FIG. 1(a) shows a foreign substrate with III-nitride template, FIG. 1(b) shows a template designed in the form of strips, FIG. 1(c) shows a schematic of a stripes design to accommodate one VCSEL on each side of the stripe, and FIG. 1(d) shows a schematic of continuous stripes for more than one VCSEL on each ELO wing.

FIGS. 2(a), 2(b), 2(c) and 2(d) are schematics similar to FIGS. 1(a), 1(b), 1(c) and 1(d), but with a growth restrict mask deposited and a window opened at a III-nitride stripe to allow ELO growth.

FIGS. 3(a), 3(b), 3(c) and 3(d) are schematics of the structures after base ELO layers are grown.

FIG. 4(a) is a schematic of the processed base design, processed ion implantation (current blocking), regrowth of a tunnel junction and current spreading layer, and a planar DBR mirror.

FIG. 4(b) is a schematic of a lateral injection VCSEL design, with top contacts prepared for bonding.

FIGS. 5(a) and 5(b) are schematics of a removal method, after attaching a VCSEL device to a carrier, using laser irradiation aimed at an open window region, with the resulting damage visible only at the open window region.

FIGS. 5(c) and 5(d) are schematics of a removal method, after attaching a VCSEL device to a carrier using SU-8 and a thermal release layer, with a chemical lift-off performed to etch the foreign substrate.

FIGS. 5(e) and 5(f) are schematics of the resulting ELO interface layers after removing the substrate.

FIGS. 5(g) and 5(h) are schematics of a final VCSEL device after processing a curved mirror DBR on the removed ELO interface.

FIGS. 5(i) and 5(j) are schematics of a short cavity VCSEL fabricated with this invention, where thinning is performed on the ELO interface while bonding VCSEL device layers to a carrier.

FIGS. 6(a) and 6(b) illustrate a process for obtaining a short cavity VCSEL by polishing the ELO base layers from the top.

FIGS. 6(c) and 6(d) are scanning electron micrograph (SEM) images of ELO GaN base layers grown on foreign substrates, which can be used for the fabrication of VCSELs with curved DBR mirrors or short cavity VCSELs.

FIGS. 6(e) and 6(f) are schematics of a continuation of the device from FIGS. 6(a), 6(b), 6(c) and 6(d), with device layers grown after polishing and the ELO interface is used for a DBR mirror after removing the substrate.

FIGS. 6(g) and 6(h) are schematics of a long cavity VCSEL, where a p-GaN side curved mirror is processed and a planar DBR mirror is processed on an ELO interface.

FIGS. 7(a) and 7(b) are schematics of a process step to achieve a curved surface ELO base layer, where FIG. 7(a) shows the host substrate has a patterned curved region covered with a growth restrict mask, and FIG. 7(b) shows the ELO growth of VCSEL device layers.

FIGS. 7(c) and 7(d) are schematics where FIG. 7(c) shows a top-side finished long cavity VCSEL before submount attachment, and FIG. 7(d) shows the final VCSEL device using an ELO interface curved surface.

FIG. 8 is a schematic of an example long cavity VCSEL with a vertical current injection configuration using the ELO interface as one of the metal contacts.

FIGS. 9(a), 9(b), 9(c), 9(d) and 9(e) are a graph and images of an experimental demonstration of obtaining curved surfaces on ELO layers, where FIG. 9(a) is a profile of the resin on the host substrate, FIG. 9(b) is the profile after the growth restrict mask is deposited, FIG. 9(c) is a host substrate prepared with curved surfaces covered in the growth restrict mask and open windows to assist ELO growth, FIG. 9(d) is the removed ELO base layers with attached curved features, and FIG. 9(e) is a laser microscope image of the successfully transferred curved feature on the ELO interface.

FIG. 10 is a flow chart of the process steps used to realize one of the discussed designs in the present invention.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

### Overview

The present invention describes a method of fabricating semiconductor devices, such as plano-concave VCSELs, by designing a growth restrict mask accordingly. As ELO is relied on in this invention, this method is easily applicable to foreign substrates, such as Sapphire, Si, SiC, SiN, GaAs, Ga₂O₃, LiAlO₂, etc., or templates of semiconductor layers, or a host substrate containing ELO engineered layers templates. ELO engineered layers templates are possible to use with a GaN-on-Sapphire substrate and with a GaN-on-Silicon substrate, etc.

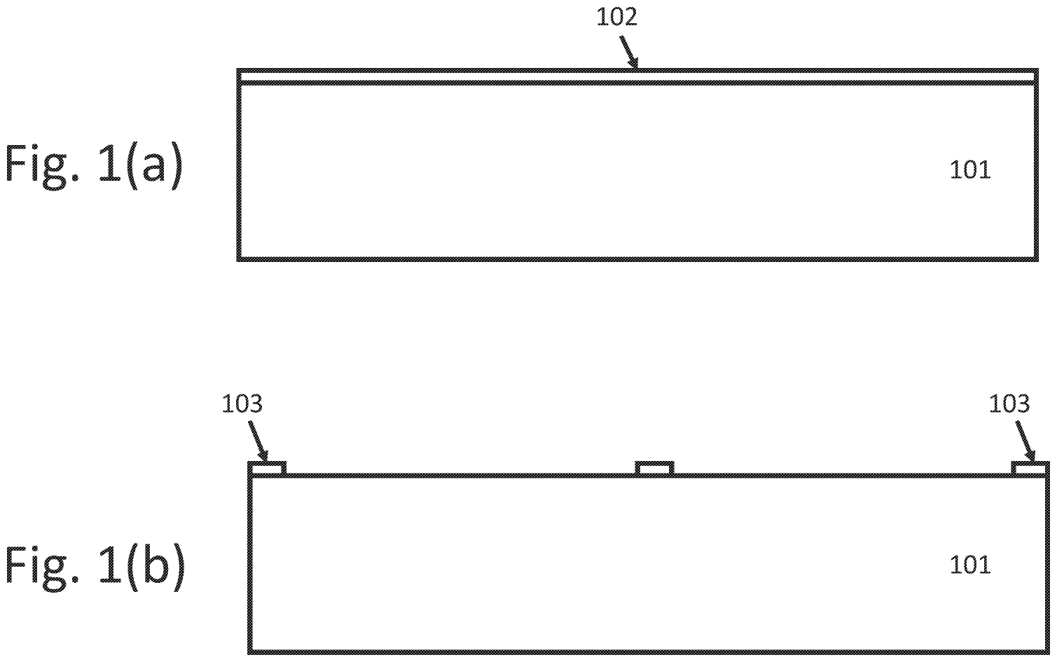

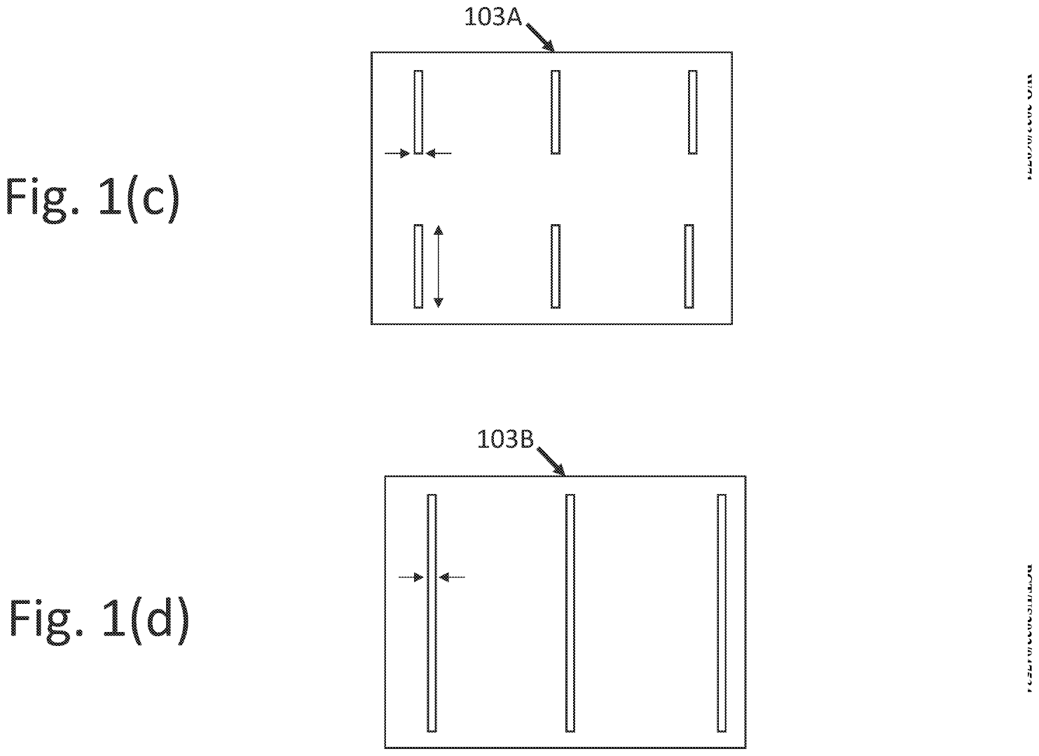

FIGS. 1(a), 1(b), 1(c) and 1(d) are schematics that illustrate a method, which comprises providing a III-nitride-based substrate 101, such as a GaN-on-Si, GaN-on-Sapphire, or bulk GaN substrate. In the case of a foreign substrate, a III-nitride template 102 can be deposited on the substrate 101, and the design of the template 102 can be a uniform layer over the host foreign substrate 101, or the template 102 can be designed only as an open area stripe 103. In such a case, areas of the host substrate 101 adjacent the open area stripe 103 can be used to process concave shapes or any user designed shapes. For example, foreign substrates such as Si and GaAs can be modified using chemical etchants more easily compared to a III-nitride layer. A III-nitride stripe 103 containing a host substrate 101, such as the stripes 103A and 103B, is shown in the schematics of FIGS. 1(c) and (d), respectively. The open area stripes 103 can also be modified to be confined to a single device by shortening their length, as shown by the stripes 103A in FIG. 1(c), or the open area stripes 103 can also be modified to be confined to a plurality of devices by increasing their length, as shown by the stripes 103B in FIG. 1(d).

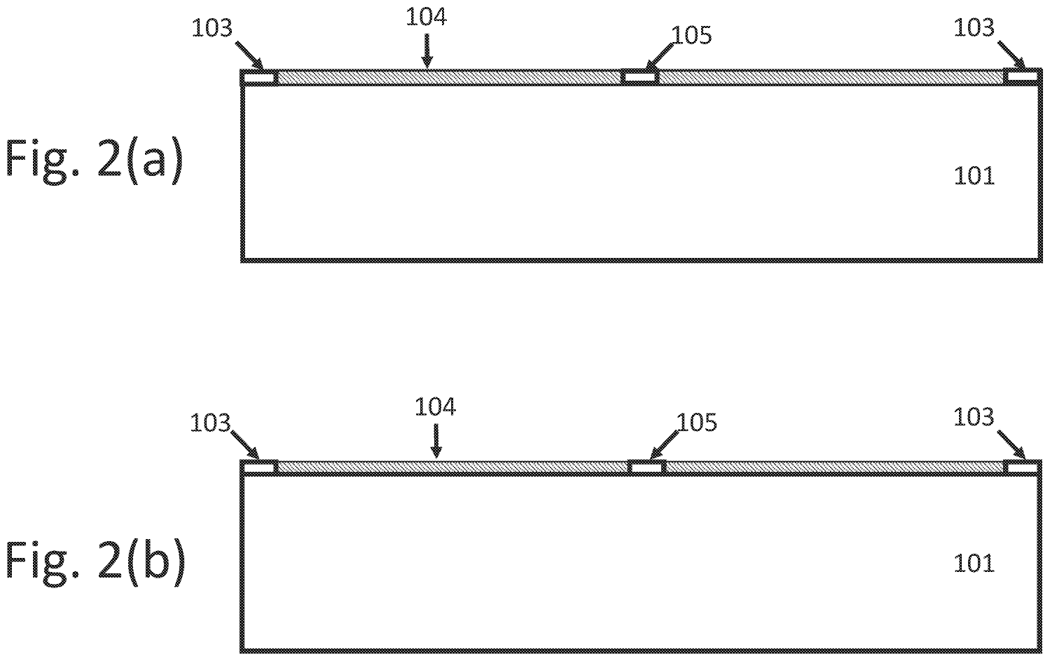

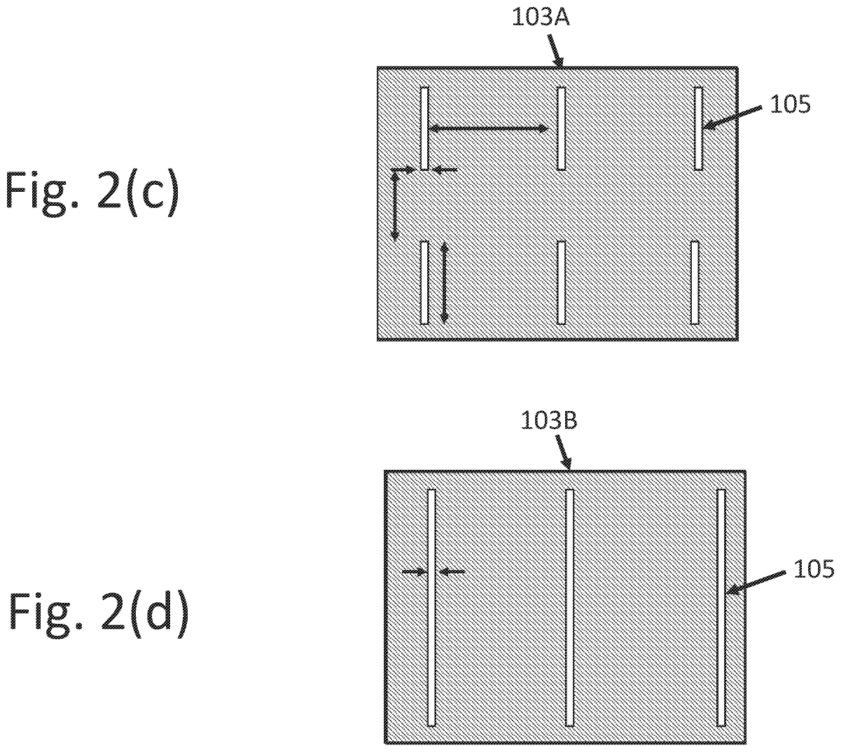

As shown in the schematics of FIGS. 2(a), 2(b), 2(c) and 2(d), a growth restrict mask 104 is formed on or above a GaN-based substrate 101. Specifically, the growth restrict mask 104 is disposed directly in contact with the substrate 101, or is disposed indirectly through a template layer 102 grown by MOCVD, etc., and made of III-nitride-based semiconductor deposited on the substrate 101, while leaving open area stripes 103, which may comprise shorter stripes 103A or longer stripes 103B.

The growth restrict mask 104 can be formed from an insulator film, for example, an SiO₂ film, deposited upon the substrate 101, for example, by a plasma chemical vapor deposition (CVD), sputter, ion beam deposition (IBD), etc., wherein the SiO₂ film is then patterned by photolithography using a predetermined photo mask and etching to include opening areas 105.

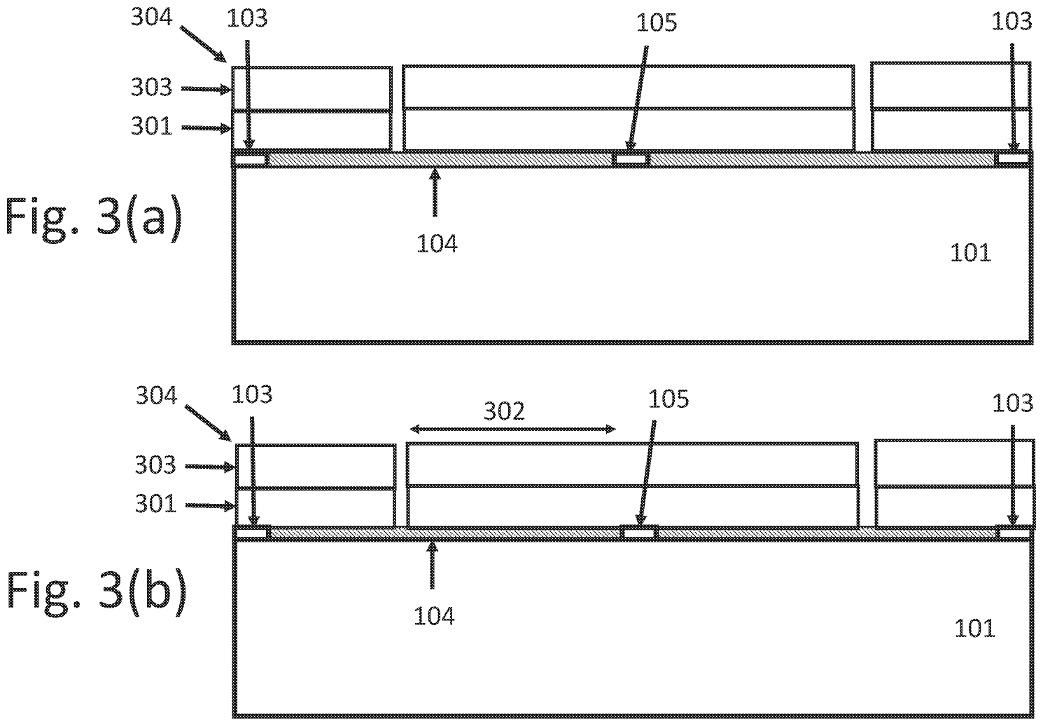

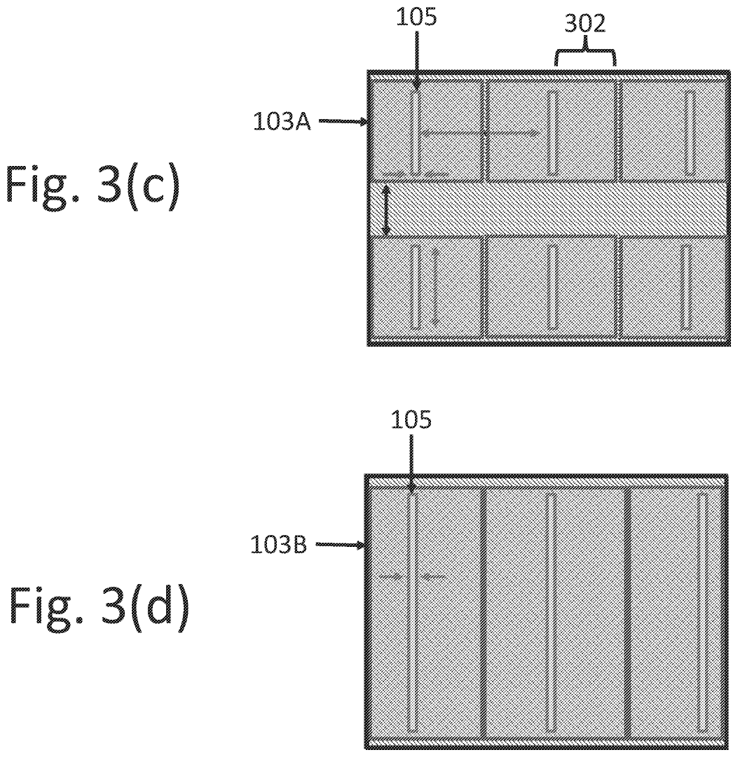

As shown in the schematics of FIGS. 3(a), 3(b), 3(c) and 3(d), epitaxial III-nitride layers 301, such as GaN-based layers, are grown by ELO on the GaN substrate 101 and the growth restrict mask 104. The growth of the ELO III-nitride layers 301 occurs first in the opening areas 105 on the GaN-based substrate 101, and then laterally from the opening areas 105 over the growth restrict mask 104. The growth of the ELO III-nitride layers 301 is stopped or interrupted before the ELO III-nitride layers 301 from adjacent opening areas 105 can coalesce on top of the growth restrict mask 104. Alternatively, the growth of the ELO III-nitride layers 301 may be continued and coalesce with neighboring ELO III-nitride layers 301. A wing 302 of the ELO III-nitride layers 301 is an area of reduced defect density on either side of the opening areas 105. Depending on the composition of the ELO III-nitride layers 301, additional III-device layers 303 are deposited on or above the ELO III-nitride layers 301, and may include an active region, p-type layer, electron blocking layer (EBL), and cladding layer, as well as other layers. Device 304 fabrication is then performed, which may include an ion implantation layer (current blocking layer) to define an aperture, and a tunnel junction containing n++/p++ layers is regrown or a transparent ITO current spreading layer is disposed over the device layers 303, before finishing the device 304 fabrication with a DBR mirror, and p and n-type contacts depositions.

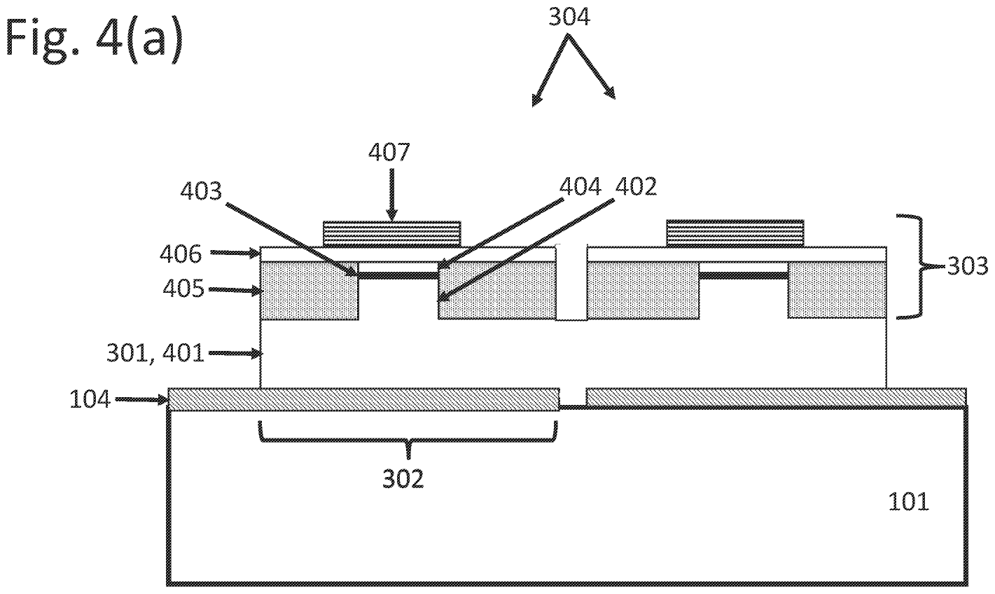

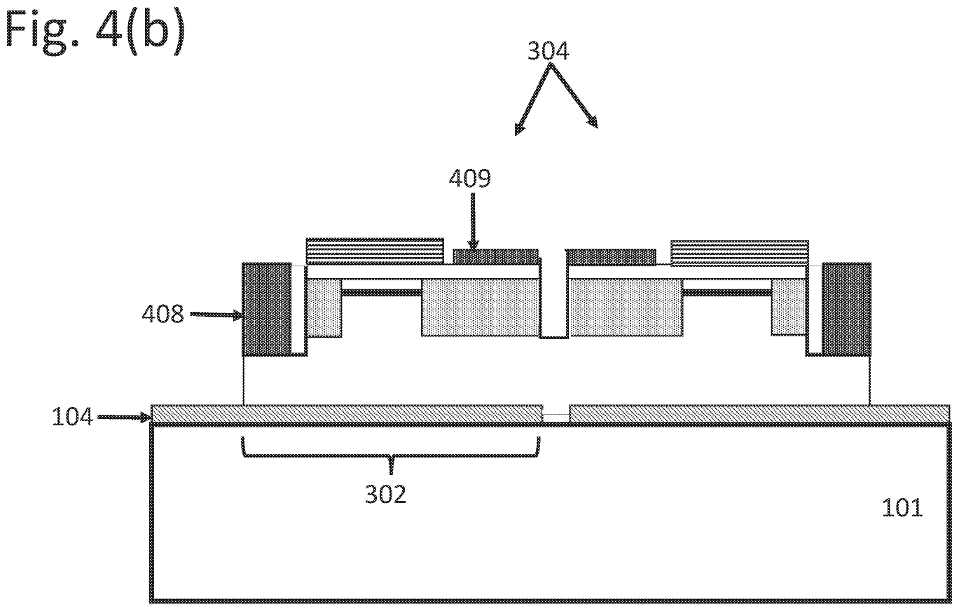

FIG. 4(a) is a schematic illustrating dual VCSELs 304, each of which is fabricated on a wing 302 of the ELO III-nitride layers 301 using III-device layers 303. Each of the VCSELs 304 include UID GaN layers 401, n-GaN layers 402, active region 403, and p-GaN layers 404, wherein a mesa is etched and then a current blocking layer 405 is deposited, followed by a tunnel junction or transparent conducting layer 406, and a DBR 407.

The design described here is referred to as a base Design I without p-contacts and n-contacts. However, in this particular design, there is the freedom to choose horizontal current injection by placing contact pads on one side of the device 304, or vertical current injection by utilizing part of the interface of the ELO wing 302, or an open window region between two ELO wings 302 in the case of two VCSELs 304 packaged as a single unit.

In this context, the base Design I uses LLO or chemical etching to obtain either a horizontal current injection configuration with a reflow curved long cavity VCSEL 304 on the n-side (referred to as Design I-A), or a vertical current injection configuration with a polished short cavity VCSEL 304 (referred to as Design I-B), or a polished and regrowth VCSEL 304 (referred to as Design I-C), or a VCSEL 304 with a concave shape transferred either onto the ELO mask 104 or the host substrate 101 (referred to as Design I-D), or a reflow curved long cavity VCSEL 304 on the p-side (referred to as Design I-E).

FIG. 4(b) is a schematic illustrating dual VCSELs 304, each of which is fabricated on a wing 302 of the ELO III-nitride layers 301 using III-device layers 303. The VCSELs 304 include UID GaN layers 401, n-GaN layers 402, active region 403, and p-GaN layers 404, wherein a mesa is etched and then a current blocking layer 405 is deposited, followed by a tunnel junction or transparent conducting layer 406, and a DBR 407. Finally, n-contacts 408 and p-contacts 409 are deposited.

### Methods of Removing Foreign Substrates

Proposed VCSEL devices 304 are fabricated on wings 302 of the ELO III-nitride layers 301 from foreign substrates 101, such as GaN-on-Si or GaN-on-Sapphire. From the base Design I structure, two versions of current injection are proposed, namely, horizontal current injection and vertical current injection structures, which are described in conjunction with Designs I-A, I-B, I-C, I-D and I-E.

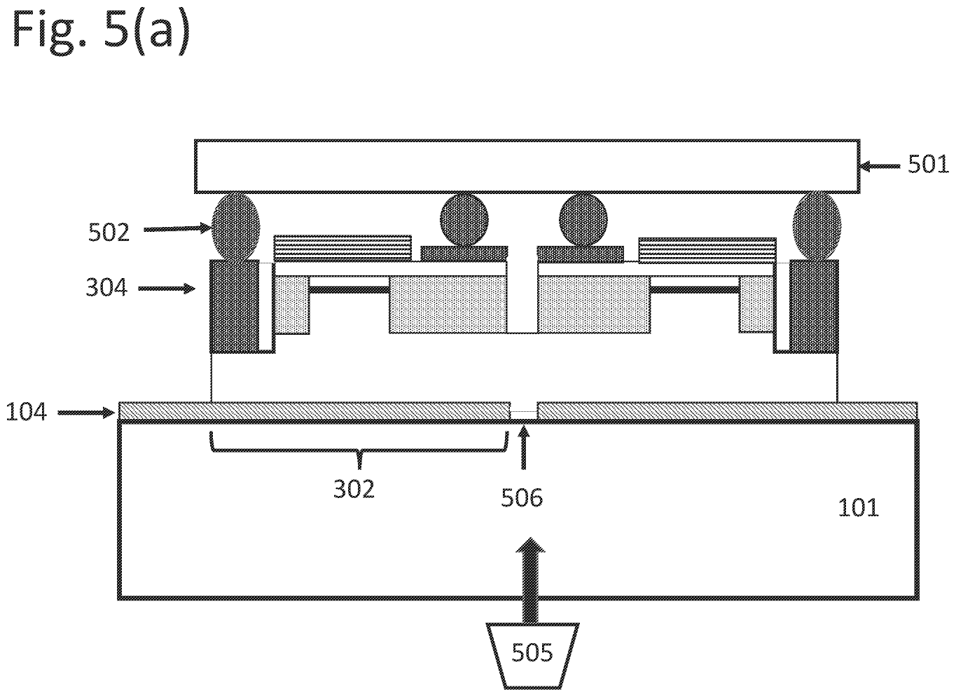

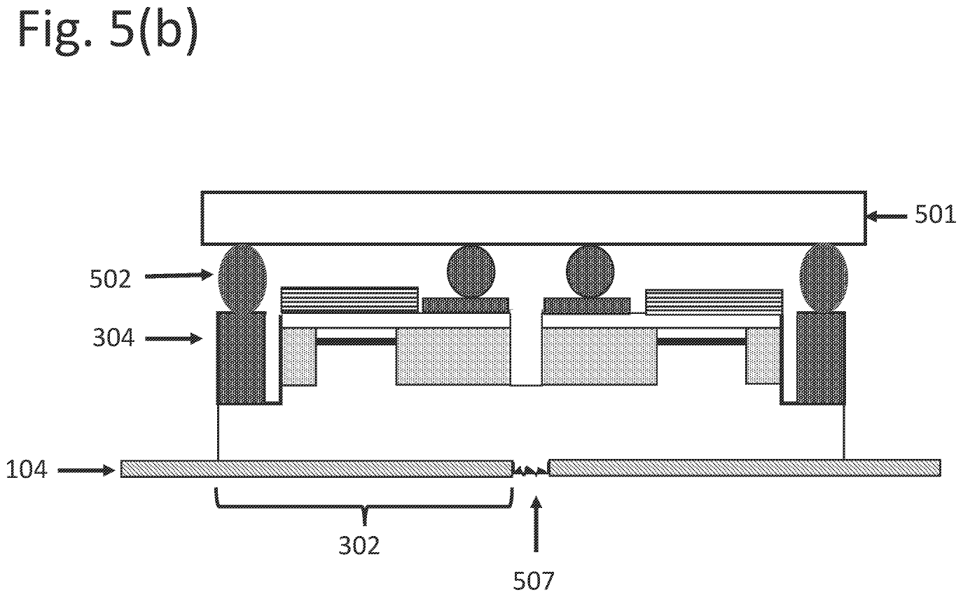

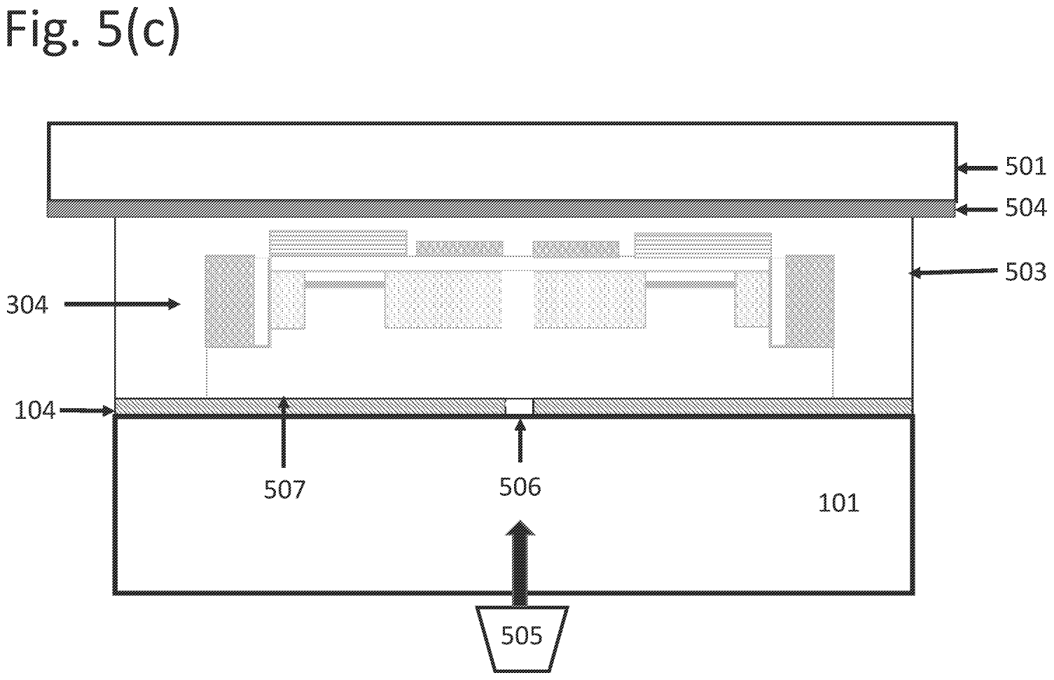

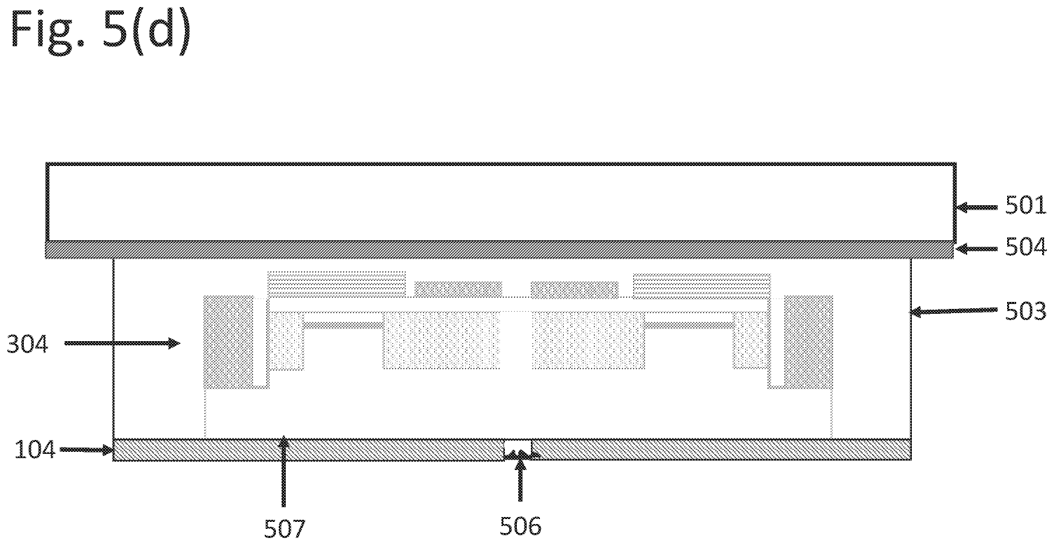

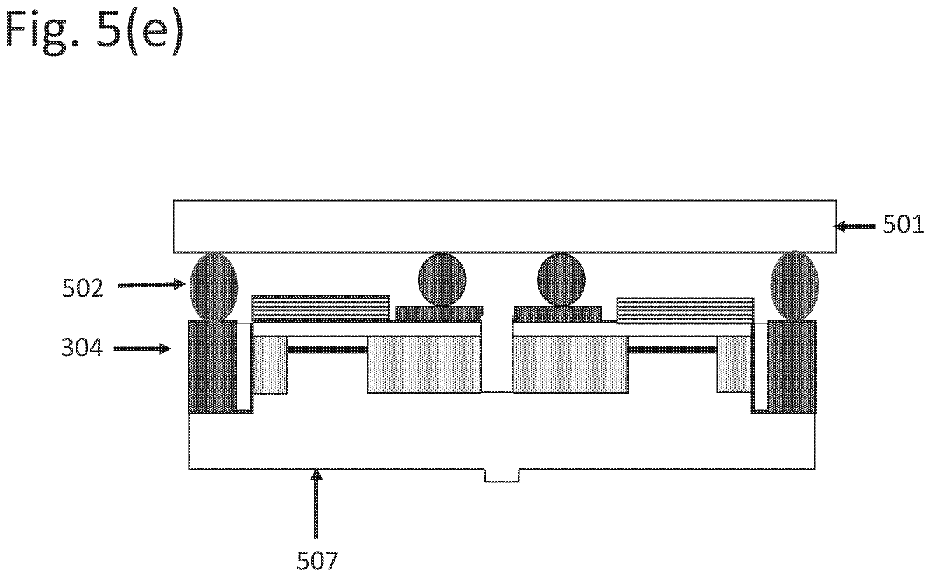

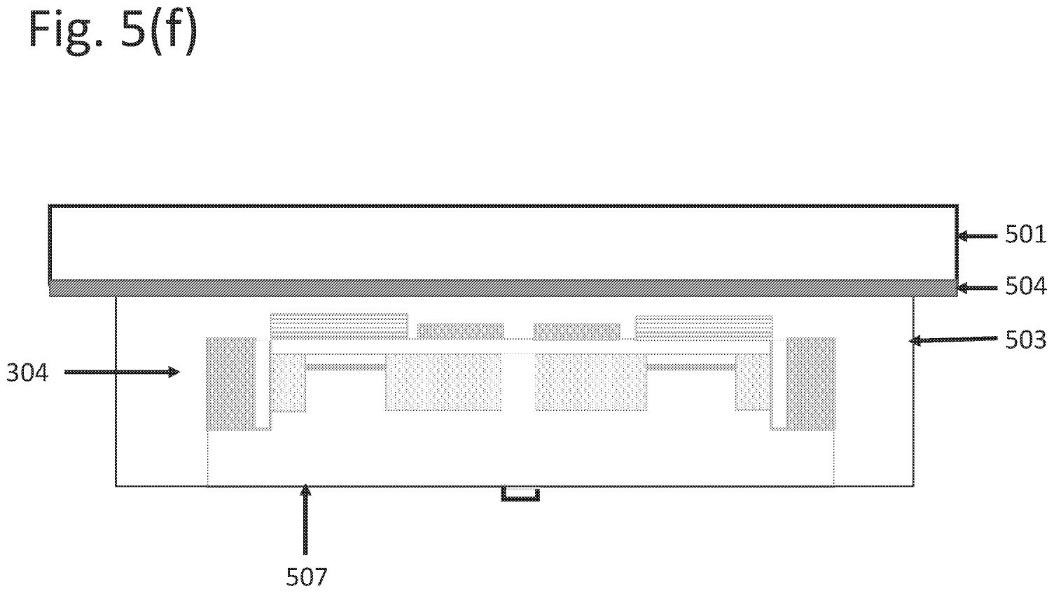

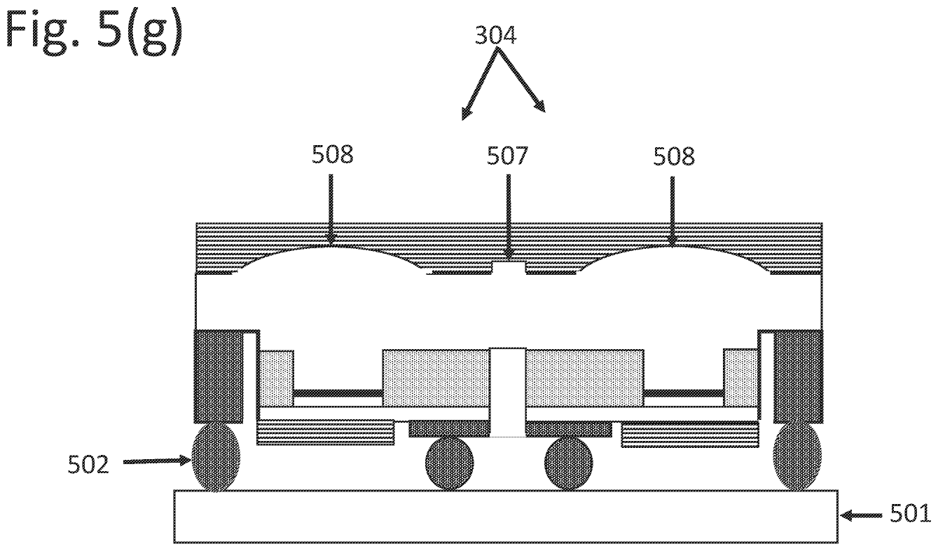

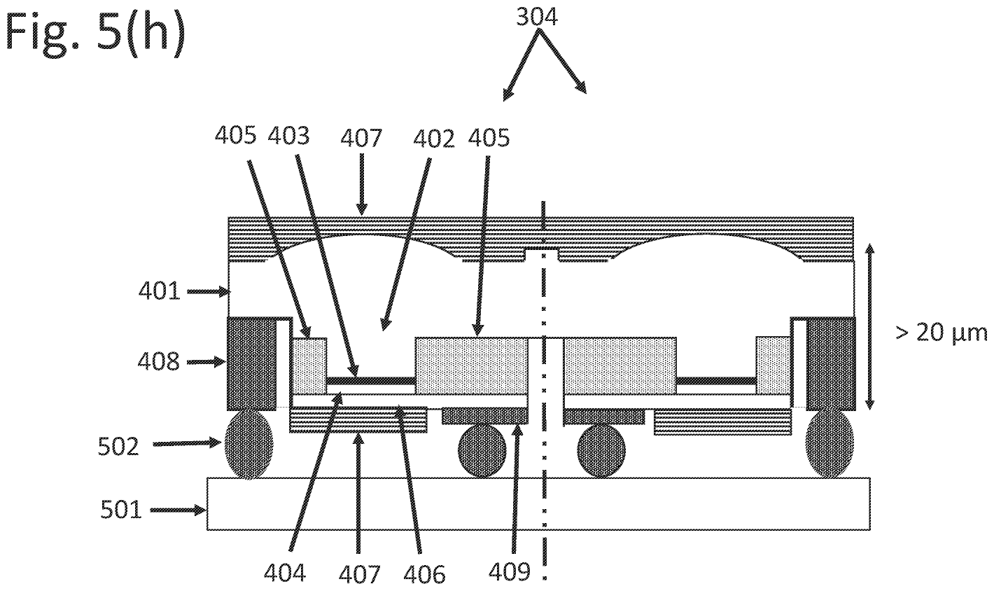

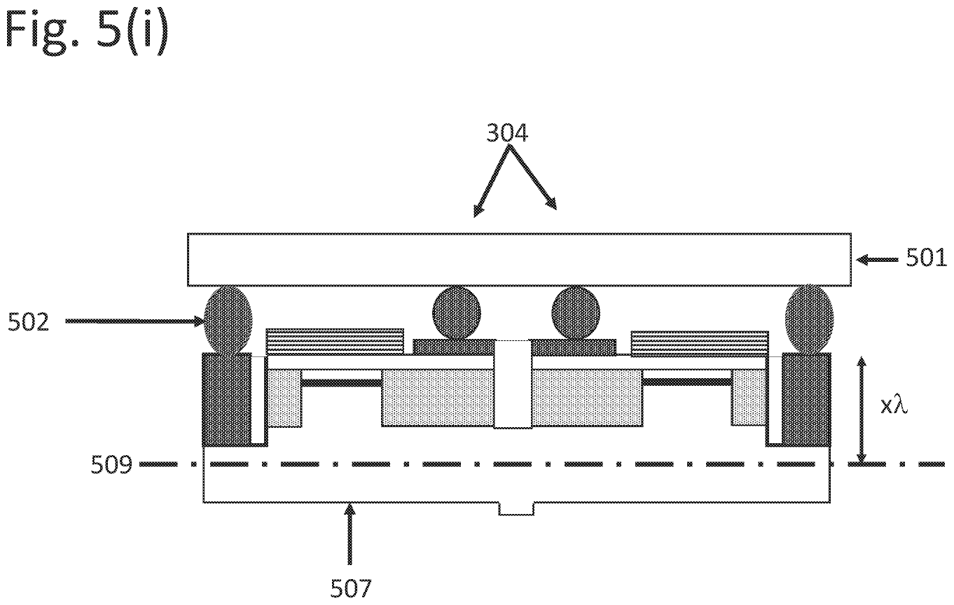

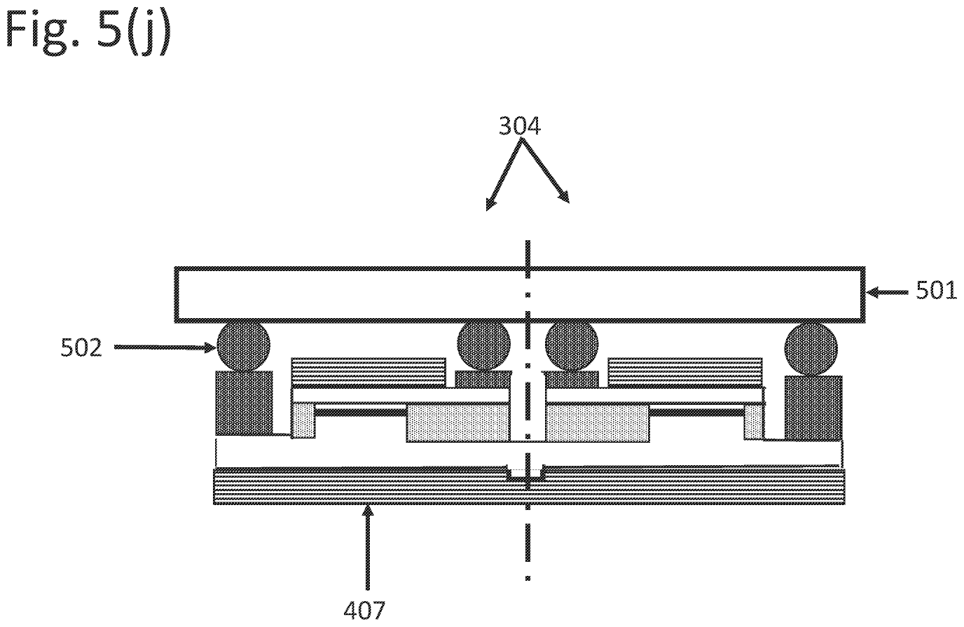

One of such design, for example, horizontal injection case removability, is illustrated in FIGS. 5(a), 5(b), 5(c) and 5(d). A carrier substrate 501, such as glass, is attached to the pre-processed VCSEL 304 using solder 502 or the like, as shown in FIG. 5(a), followed by LLO of the substrate 101, as shown in FIG. 5(b). The attachment of the carrier substrate 501 can be done after planarizing, for example, using a photoresist 503, such as SU-8, as shown in FIG. 5(c). For example, isolated VCSELs 304 are passivated by several microns of photoresist 503, and the resulting structures can then be captured by a thermal release tape 504 onto the carrier substrate 501.

LLO is a method that is proven to be a fast and non-chemical method for removing a thin GaN layer stack from a Sapphire substrate, and then transferring it onto a carrier substrate. The first LLO-based GaN film detachment from a Sapphire substrate was demonstrated using a third-harmonic Q-switched Nd:YAG laser with a 355 nm wavelength. Laser pulses with this wavelength were transmitted through the Sapphire substrate onto the GaN/Sapphire interface and absorbed in the GaN interface region. The photon absorption induced decomposition of GaN into metallic Ga and gaseous N₂.

Conventionally, LLO can be performed using a variety of short-pulsed lasers, including the excimer lasers (e.g., 193 nm ArF, 248 nm KrF, and 308 nm XeCl lasers) and Q-switched lasers (e.g., with frequency-tripled (355 nm) or frequency-quadrupled (266 nm) nanosecond lasers). In the optoelectronic industry, KrF excimer lasers with a 248 nm emission wavelength are often applied for the LLO procedure using a raster scanning method. This conventional LLO approach requires direct absorption in the semiconductor.

As shown in FIGS. 5(a) and 5(c), after processing the VCSEL 304 on the ELO wing 302, the carrier substrate 501 is attached and then a laser 505 is focused onto an open window region 506 from the back of the host substrate 101 (GaN-on-Sapphire). In this invention, laser 505 irradiation is selective only at the open window region 506. As the laser 505 can be focused very narrowly at the open window region 506, and there is no need of irradiation over the whole VCSEL 304 and, as a result, this method is very advantageous to lift-off the fabricated VCSEL 304 without significant damage to the device layers of the VCSEL 304. Moreover, the interface 507 of the ELO wing 302 with the substrate 101 is fully covered with an ELO mask 104 during the irradiation, which will protect from further damage leaving Ga-melt only at the interface 507, as shown in FIGS. 5(b) and 5(d). A similar process would be carried out for lifting off of the GaN-on-Si template 102, except using a chemical like KOH, instead of LLO.

The ELO mask 104 is then dissolved using a chemical solution, for example BHF, when an SiO₂ ELO mask 104 is used. The resulting VCSEL device units 304 are placed onto the carrier substrate 501 with an open interface 507, as shown in FIGS. 5(e) and 5(f). The interface 507 is further modified for the process of fabricating a resonant cavity DBR mirror and to dispose metal contacts for vertical injection, as described below.

### VCSEL Design I-A

In Design I-A, resin disks with desired diameters are photolithographed on the interface 507 of the ELO wing 302. Alternatively, one may use printers to place resist disks, when uniform spin coating poses challenge due to the discreteness of the ELO layers 301. By heating the specimen, the disks melt into droplets. RIE can be used to transfer the surficial shape of the resin droplets onto the interface 507 by removing them as sacrificial masks, which will leave a lens-shaped surface on the interface 507. An n-side DBR, for example, Ta₂O₅/SiO₂ bilayers, is deposited to form a curved mirror 508, as shown in FIG. 5(g).

FIG. 5(h) shows the completed VCSELs 304, which include UID GaN layers 401, n-GaN layers 402, active region 403, p-GaN layers 404, current blocking layer 405, tunnel junction or transparent conducting layer 406, DBRs 407, n-contacts 408 and p-contacts 409.

This design is specially dedicated for long cavity VCSELs 304, where generally resonant cavity lengths are more than 20 μm.

### VCSEL Design I-B

Design I-B can be used in designing short cavity VCSELs 304, wherein the resonant cavity thickness is on the order of a few wavelengths, for example, xλ=7λ, 13λ, 23λ, etc., where λ is the emission wavelength of the device. Short cavity lengths can be used to obtain a single longitudinal mode emission due to the large mode spacing. In this design, after removing the host substrate 101, thinning to line 509 can be performed on the interface 507 to obtain a desirable cavity length, as shown in FIG. 5(i), and then a second DBR mirror 407 can be disposed at the interface 507 to complete the VCSEL 304 fabrication, as shown in FIG. 5(j).

### VCSEL Design I-C

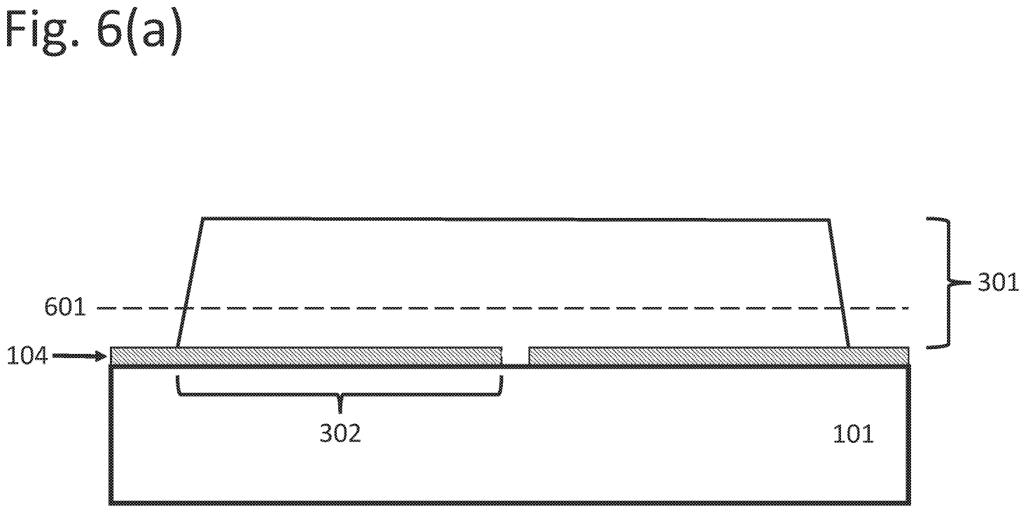

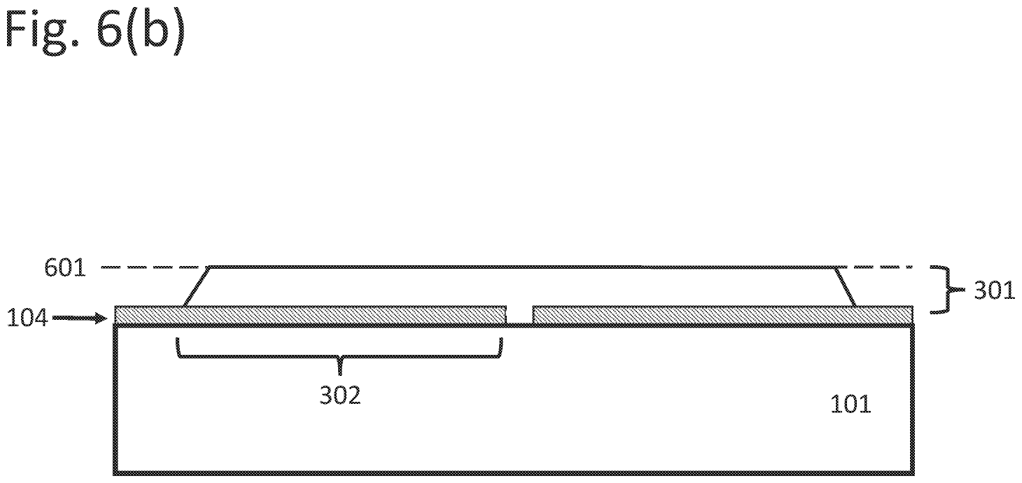

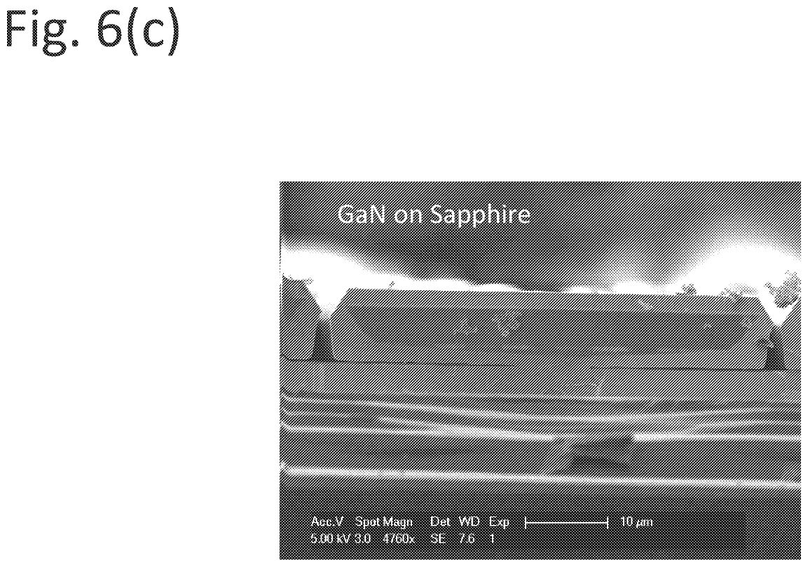

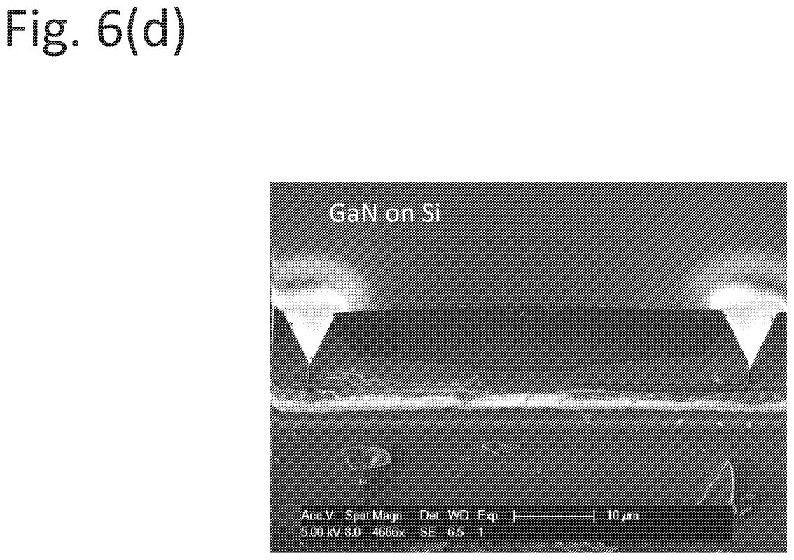

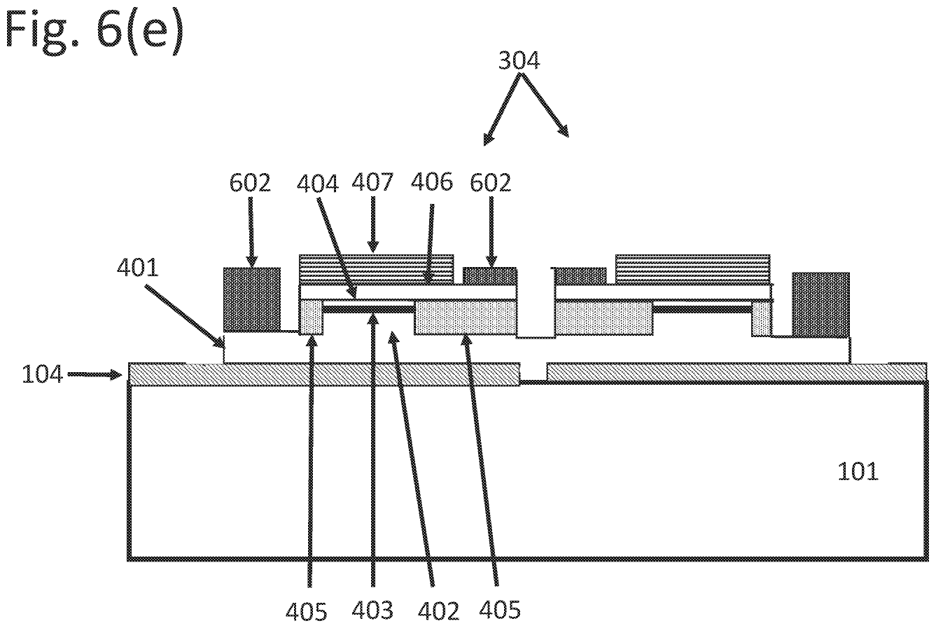

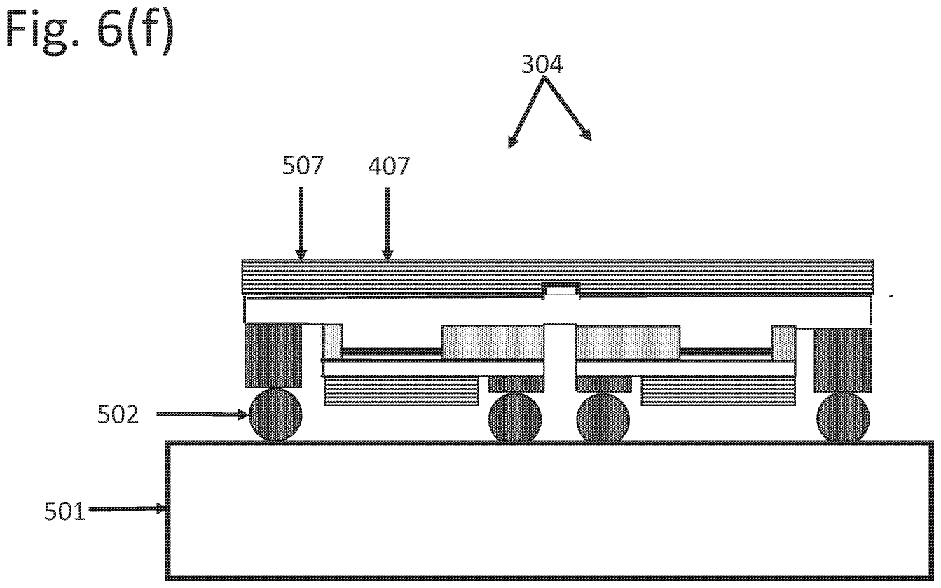

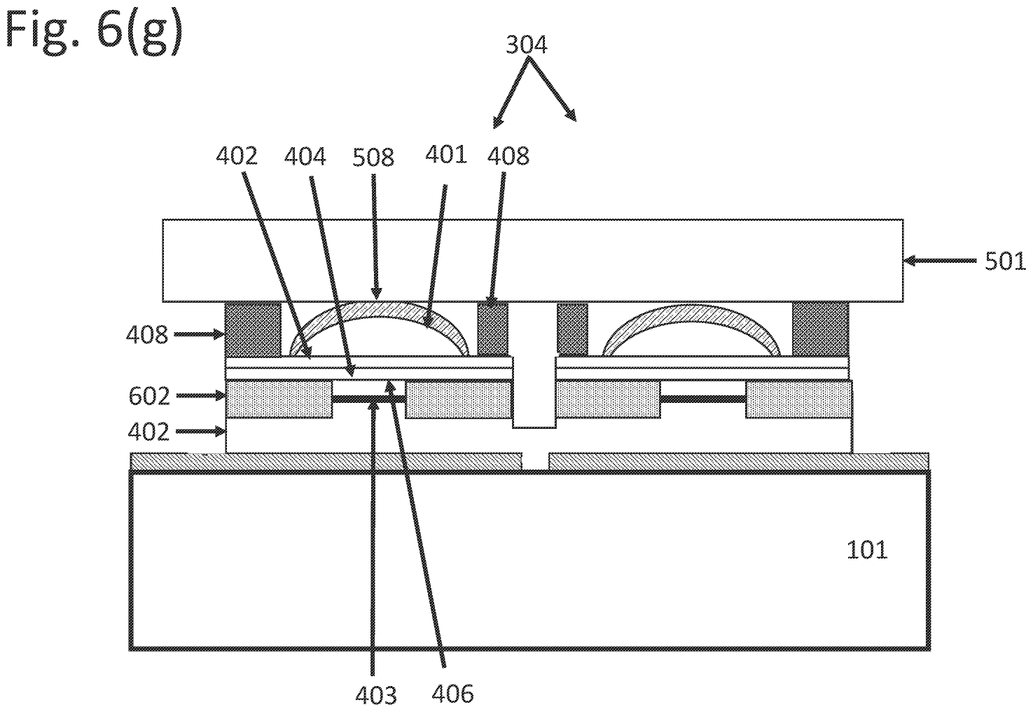

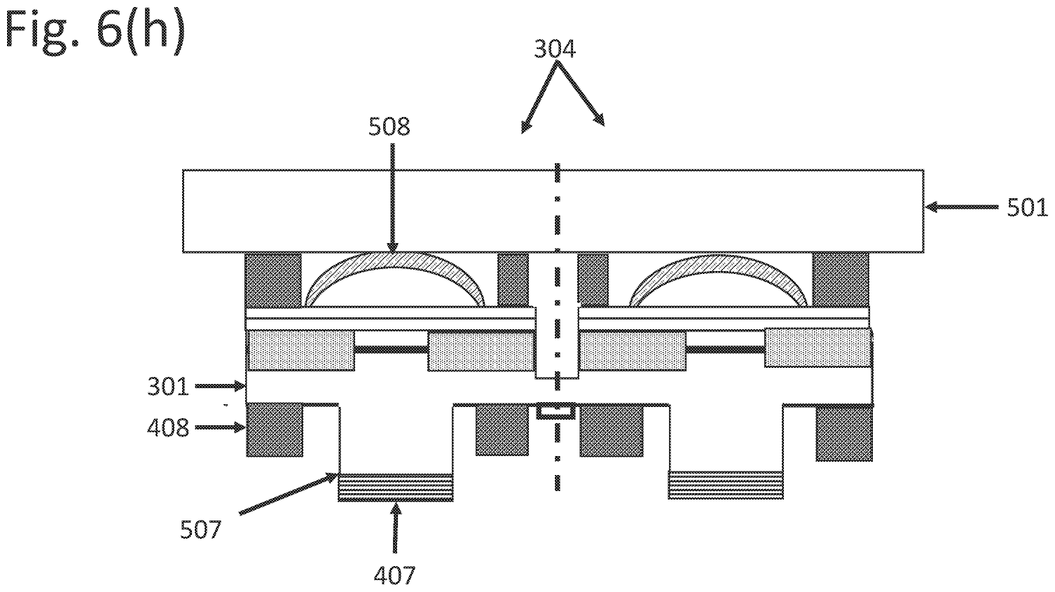

Design I-C is an alternative approach to achieve a short cavity VCSEL as in Design I-B, but by polishing from a top surface before introducing an active region and p-GaN layers onto an ELO base layer 301. After reaching a desired ELO wing 302 width, as shown in FIG. 6(a), the ELO III-nitride layers 301 are polished from a top surface to reach a point 601, as shown in FIG. 6(b), which is a desired pre-calculated value, and then regrowth is performed to grow the III-nitride semiconductor device layers 303 including an active region and p-GaN layers. Then, a process is performed to fabricate a VCSEL 304 structure containing a current blocking layer, current spreading layer, DBR mirror, and one or more metal contacts. Using one of the methods described in the substrate removal, the host substrate 101 is removed and the interface 507 of the ELO wing 302 is used to deposit a second DBR mirror.

FIG. 6(c) is a SEM image showing a GaN-on-Sapphire substrate 101 with ELO III-nitride layers 301. FIG. 6(d) is a SEM image showing a GaN-on-Si substrate 101 with ELO III-nitride layers 301.

The resulting VCSELs 304, before lift-off, are shown in FIG. 6(e), and include UID GaN layers 401, n-GaN layers 402, active region 403, and p-GaN layers 404, wherein a mesa is etched and then a current blocking layer 405 is deposited, followed by a tunnel junction 406, a DBR 407, and an ion-implanted aperture 602. After lift-off, with a second DBR mirror 407 disposed at the interface 507 to complete the VCSEL 304 fabrication, are shown in FIG. 6(f).

### VCSEL Design I-D

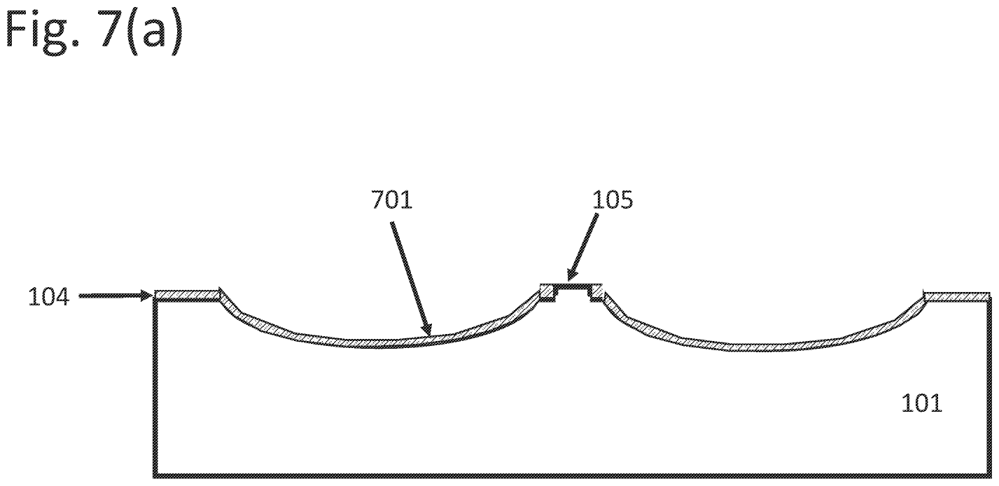

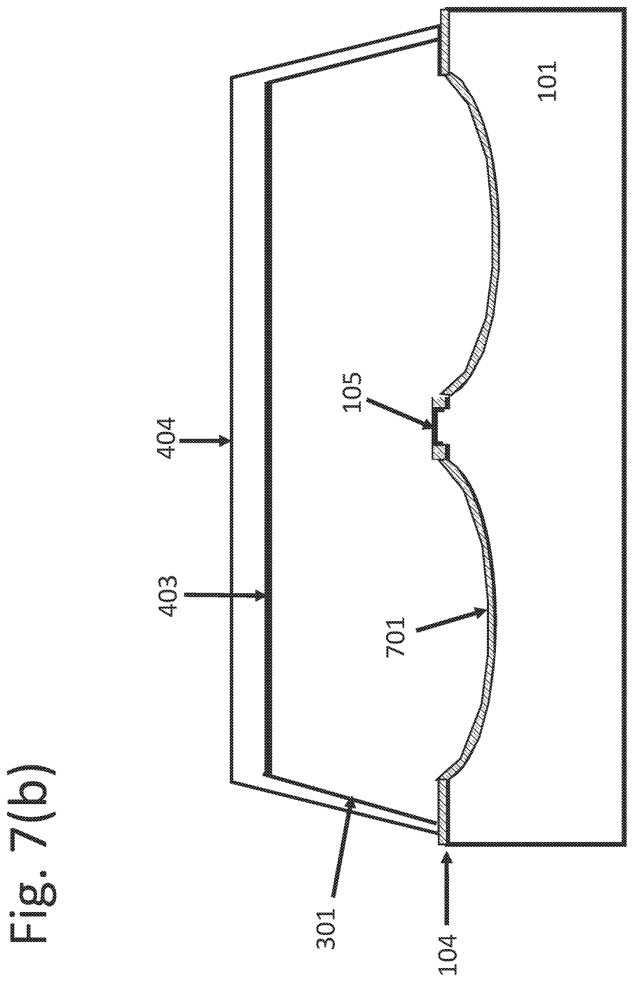

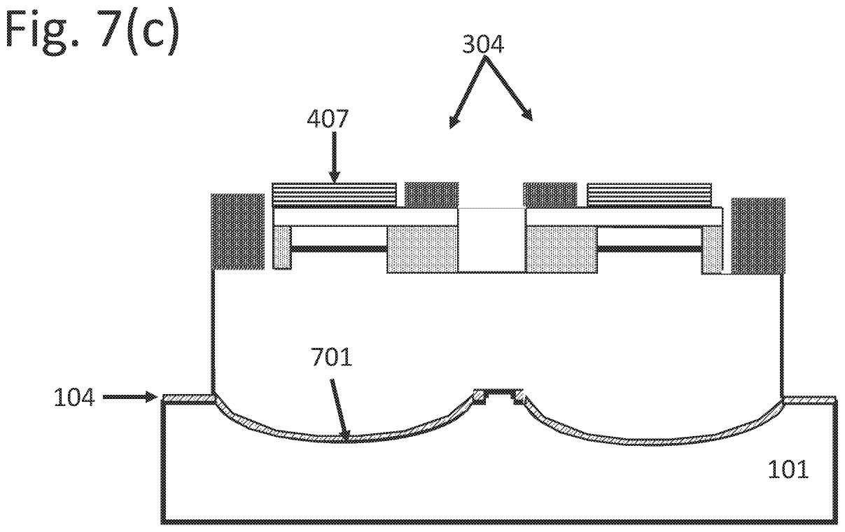

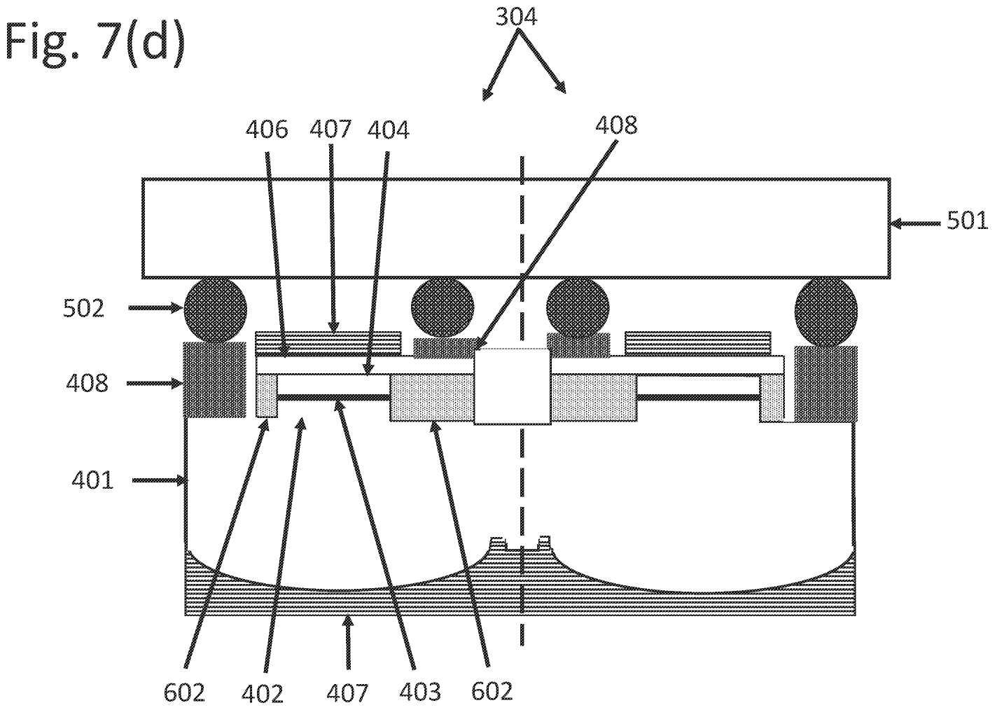

Design I-D replicates the long cavity VCSEL of Design I-A; however, no resist reflow on the interface 507 is needed to achieve a curved mirror 508. Resist reflow is used at the first stage when preparing the ELO mask 104. For example, as shown in FIG. 7(a), a concave shape 701 is transferred either onto a host substrate 101 or onto the ELO mask 104 material. The transfer process may involve nano-imprint or resist disk thermal reflow mechanisms. Then, similar to previous designs, open areas 105 are opened on the GaN-on-Si or GaN-on-Sapphire templates 102 to grow the base ELO layers 301, followed by the VCSEL device layers 303, including UID GaN layers 401, n-GaN layers 402, active region 403, and p-GaN layers 404, as indicated in FIG. 7(b).

Specifically, FIGS. 7(a) and 7(b) are schematics that illustrate a process step to achieve a curved surface shape 701 in the ELO base layer 301, where FIG. 7(a) shows the host substrate 101 has a patterned curved region 701 covered with a growth restrict mask 104, and FIG. 7(b) shows the ELO III-nitride layers 301 and the device layers 401, 402, 403, 404 of the VCSEL 304. A front-end process is then carried out to process a current blocking layer, current spreading layer, DBR mirror, metal contacts, etc., as shown in FIG. 7(c). Next, the host substrate 101 is removed using either LLO in the case of GaN-on-Sapphire or a chemical etchant in the case of GaN-on-Si, and after lift-off, with a second DBR mirror 407 disposed at the interface 507 to complete the VCSEL 304 fabrication, which includes UID GaN layers 401, n-GaN layers 402, active region 403, p-GaN layers 404, tunnel junction 406, DBRs 407, n-contacts 408, and ion-implanted aperture 602, as shown in FIG. 7(d).

### VCSEL Design I-E

Design I-E replicates the long cavity VCSEL design I-A; however, no resist reflow on the interface 507 was needed to achieve a curved mirror 508. The resist reflow process is performed on a p-side of the device 304.

As shown in FIG. 6(g), a long cavity VCSEL 304 is fabricated on the ELO wing 302 of the hetero-substrate 101 including UID GaN layers 401, n-GaN layers 402, active region 403, p-GaN layers 404, tunnel junction 406, n-contacts 408, ion-implanted aperture 602, and a first curved mirror 508 on a p-side of the VCSEL 304. As shown in FIG. 6(h), the devices 304 are lifted off using the carrier substrate 501. Then, the ELO wing interface 507 is used for a second flat DBR mirror 407 on an n-side of the VCSEL 304, along with n-contacts 408. In this embodiment, the ELO III-nitride layers 301 may be polished, as described in the Design I-C, after the substrate 101 is removed and before the second flat DBR mirror 407 is disposed on the ELO wing interface 507.

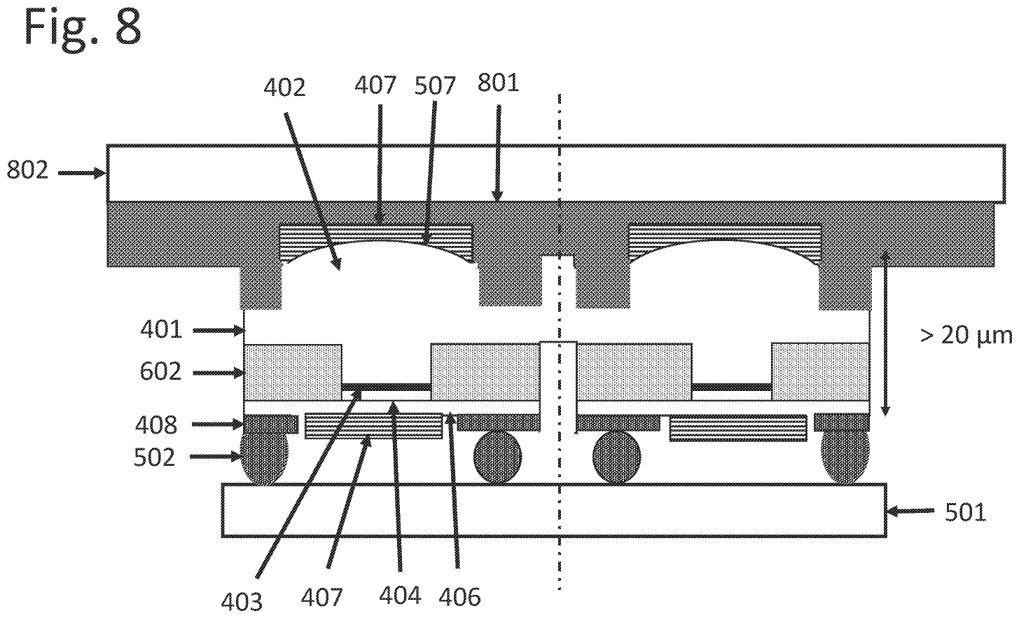

FIG. 8 is a schematic of an example long cavity VCSEL 304 with a vertical current injection configuration, using metal 801 deposited on the ELO interface 507, which bonds the VCSEL 304 to another carrier 802, as an n-contact. The long cavity VCSEL 304 otherwise includes UID GaN layers 401, n-GaN layers 402, active region 403, p-GaN layers 404, tunnel junction 406, DBRs 407, n-contacts 408, and ion-implanted aperture 602.

### Fabrication Steps

The typical fabrication steps for this invention are described in more detail below:

Step 1: Start with forming a growth restrict mask 104, which can be achieved by the following. Place a growth restrict mask 104 on a host substrate 101. The growth restrict mask 104 is patterned either using nano-imprint lithography, or a desired shape can be transferred onto the growth restrict mask 104 using photolithography plus wet etching or photolithography plus dry etching. Alternatively, a planar mask 104 may be used

Step 2: A plurality of striped opening areas 105 are opened on the substrate 101, wherein the substrate 101 is a III-nitride-based semiconductor, or the substrate is a hetero-substrate 101 such as Sapphire, Si, SiC, SiN, GaAs, Ga₂O₃, LiAlO₂, etc., or the substrate 101 includes a template 102.

Step 3: A plurality of ELO III-nitride layers 301 are grown upon the substrate 101 using the growth restrict mask 104, such that the growth extends in a direction parallel to the striped opening areas 105 of the growth restrict mask 104, the ELO III-nitride layers 301 take the shape designed on the growth restrict mask 104, and the designed pattern is transferred onto the interface 507, which is a surface between the ELO III-nitride layers 301 and the growth restrict mask 104. In the case of a planar mask 104, the interface 507 is a planar surface.

Step 4: Fabricate a VCSEL 304 on the wing 302 of the ELO III-nitride layers 301, mostly on a flat surface region, by conventional methods.

Step 5: Divide device 304 units and isolate the device 304 units on the host substrate 101.

Step 6: Attach a submount or carrier 501.

Step 7: Irradiate or chemically etch to lift-off the host substrate 101.

Step 8: Separate the device 304 units from the host substrate 101.

Step 9: Dissolve the growth restrict mask 104 using a chemical etchant, such as a buffered hydrofluoric acid (BHF) or a hydrofluoric acid (HF).

Step 10: Place a second DBR 407 on the ELO wing interface 507, or prepare a curved mirror surface 701 using resist reflow and place the second DBR 407.

### Forming a Growth Restrict Mask

In one embodiment, the GaN-based layers 301 are grown by ELO on the growth restrict mask 104 comprised of SiO₂, wherein the GaN-based layers 301 may or may not coalesce on top of the growth restrict mask 104.

The growth restrict mask 104 is comprised of opening area stripes 103, wherein the stripes 103 between the opening areas 105 have a width of 1 μm-20 μm and an interval of 10 μm-100 μm. If a nonpolar substrate 101 is used, the opening areas 105 are oriented along a <0001> axis. If a semipolar (20-21) or (20-2-1) substrate 101 is used, the opening areas 105 are oriented in a direction parallel to [−1014] or [10-14], respectively. Other planes of the substrate 101 may be used as well, with the opening areas 105 oriented in other directions.

The present invention can obtain high quality III-nitride semiconductor layers 301 using the growth restrict mask 104. As a result, the present invention can also easily obtain devices with reduced defect density, such as dislocation and stacking faults. These techniques can be used with hetero-substrates 101, such as Sapphire, Si, SiC, SiN, GaAs, Ga₂O₃, LiAlO₂, etc., as long as the substrate 101 enables growth of the ELO GaN-based layers 301 through the growth restrict mask 104.

### Patterning the Growth Restrict Mask

Before creating the opening areas 105 on the growth restrict mask 104, a pre-process is performed on the growth restrict mask 104. This application focuses on preparing VCSELs. The opening area stripes 103 can be of limited length 103A, such as shown in FIGS. 2(a), 2(b), 2(c) and 2(d), in order to accommodate a VCSEL on each wing, or can be stripes 103 of long length 103B, to accommodate several VCSEL devices on each wing 302. In certain cases, for example, Design I-D, a concave shape is transferred either onto the ELO mask 104 or the host substrate 101, and then opening areas 105 for ELO growth. Opening areas 105 are chosen such that growth parameters optimizes larger ratios of wing 302 to layer 301 thickness.

### Growing a Plurality of Epitaxial Layers on the Substrate Using the Growth Restrict Mask

The III-device layers 303 are grown on the ELO GaN-based layers 301 by conventional methods. In one embodiment, MOCVD is used for the epitaxial growth of island-like III-nitride semiconductor layers, including both the ELO GaN-based layers 301 and the III-device layers 303. The island-like III-nitride semiconductor layers 301, 303 are separated from each other, because the MOCVD growth is stopped before the ELO GaN-based layers 301 coalesce.

Trimethylgallium (TMGa), trimethylindium (TMIn) and triethylaluminium (TMAI) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl) magnesium (Cp₂Mg) are used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

### ELO of Limited Area Epitaxy (LAE) III-Nitride Layers

In the prior art, a number of pyramidal hillocks have been observed on the surface of m-plane III-nitride films following growth. [See, for example, US Patent Application Publication No. 2017/0092810.] Furthermore, a wavy surface and depressed portions have appeared on the growth surface, which made the surface roughness worse. This is a very severe problem. For example, according to some papers, a smooth surface can be obtained by controlling an off-angle (>1 degree) of the substrate's growth surface, as well as by using an N₂ carrier gas condition. These are very limiting conditions for mass production, however, because of the high production costs. Moreover, GaN substrates have a large fluctuation of off-angles to the origin from their fabrication methods. For example, if the substrate has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

The present invention solves these problems as set forth below:
1. The growth area is limited by the area of the growth restrict mask 104 from the edges of the substrate 101.
2. The substrate 101 is a nonpolar or semipolar III-nitride substrate 101 that has off-angle orientations ranging from −16 degrees to +30 degrees from the m-plane towards the c-plane and C-plane. Alternatively, a hetero-substrate 101 with a III-nitride-based semiconductor layer 102 deposited thereon may be used, wherein the layer 102 has an off-angle orientation ranging from +16 degrees to −30 degrees from the m-plane towards the c-plane.
3. The island-like III-nitride semiconductor layers 301, 303 have a long side that is perpendicular to an a-axis of the III-nitride-based semiconductor crystal.
4. During MOCVD growth, a hydrogen atmosphere can be used.

In this invention, it can be used a hydrogen atmosphere during a non-polar and a semi-polar growth.

In one embodiment, the growth pressure ranges from 60 to 760 Torr, although the growth pressure preferably ranges from 100 to 300 Torr to obtain a wide width for the island-like III-nitride semiconductor layers 301, 303: the growth temperature ranges from 900 to 1200° C. degrees; the V/III ratio ranges from 10-30,000; the TMG is from 2-20 sccm; NH₃ ranges from 0.1 to 10 slm; and the carrier gas is only hydrogen gas, or both hydrogen and nitrogen gases. To obtain a smooth surface, the growth conditions of each plane needs to be optimized by conventional methods.

After growing for about 2-8 hours, the ELO GaN-based layers 301 will have a thickness of about 1-50 μm and a bar width of about 50-150 μm.

### Fabricating the Device

The device 304 is fabricated at a flat surface region of the ELO wing 302 by conventional methods, wherein various device 304 designs are possible. For example, VCSELs, current blocking regions and regrowth of tunnel junctions or placing transparent conducting layers, like ITO and metal contacts and DBR mirrors, may be are necessary. These can be fabricated on the p-side of the VCSEL 304 before removing host substrate 101.

### Forming a Structure for Separating Device Units

The aim of this step is to isolate the device 304 units from the host substrate 101 using the ELO III-nitride device layers 301. At least two methods can be used to transfer the device 304 units onto a carrier substrate 501.

In one method, using a selective etching mask, the III-nitride device layers 303 are separated on the host substrate 101 by etching to expose at least the growth restrict mask 104.

In another method, scribing by a diamond tipped scriber or laser scriber can be performed, or other methods, such as RIE (Reactive Ion Etching) or ICP (Inductively Coupled Plasma) etching could be used to isolate device 304 units.

Then, the isolated VCSEL device 304 units are filled with a photoresist 503, such as SU-8, and attached to the carrier substrate 501 via a thermal release film 504, or simply bonded to a carrier wafer 501 using solder 502 and the removing steps then performed.

### Forming a Curved Structure on ELO Mask

For the device 304 described in Design I-D, the growth restrict mask 104 or the host substrate 101 must be pre-processed to create a curved feature 701 for transfer onto the interface 507 of the ELO Layer 301.

To transfer a concave shape pattern 701 onto the interface 507 of the ELO layer 301, the mask 104 must include the same pattern. A very promising patterning technique is nano-imprint technology. Firstly, a stamp with the inverse pattern is fabricated, the so-called master. By pressure or capillary forces, the pattern is printed into a resist deposited onto the host substrate 101 or the mask 104 material. After heating and/or UV-curing, the stamp is removed and the resist can act as an etching mask. The patterning process can be done on a wafer-scale and thus offers high throughput. The master pattern has to be fabricated first by conventional photolithography techniques.

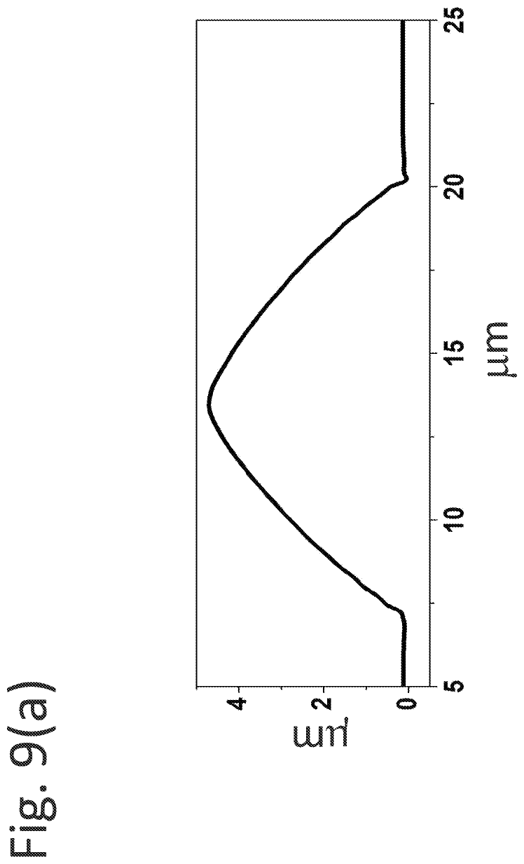

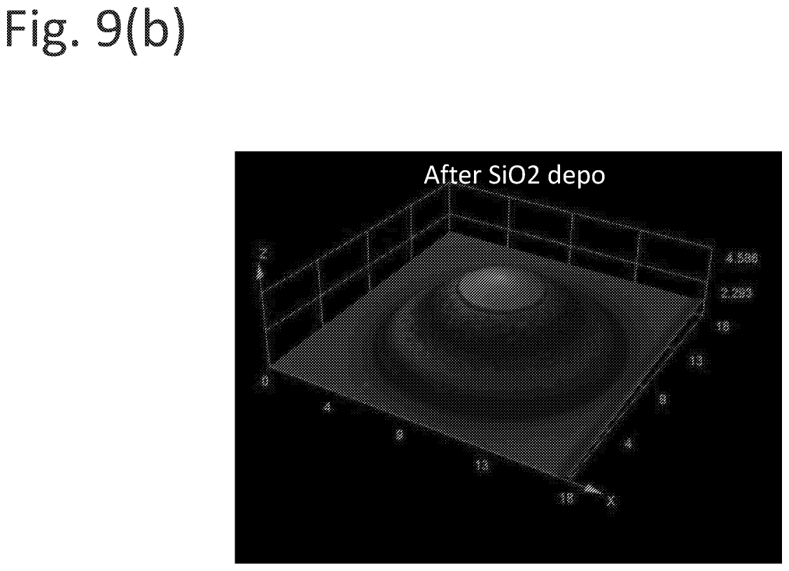

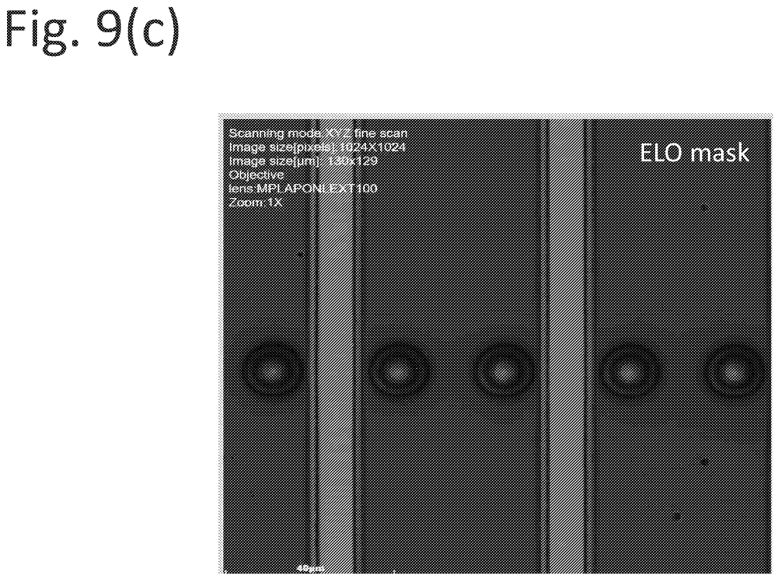

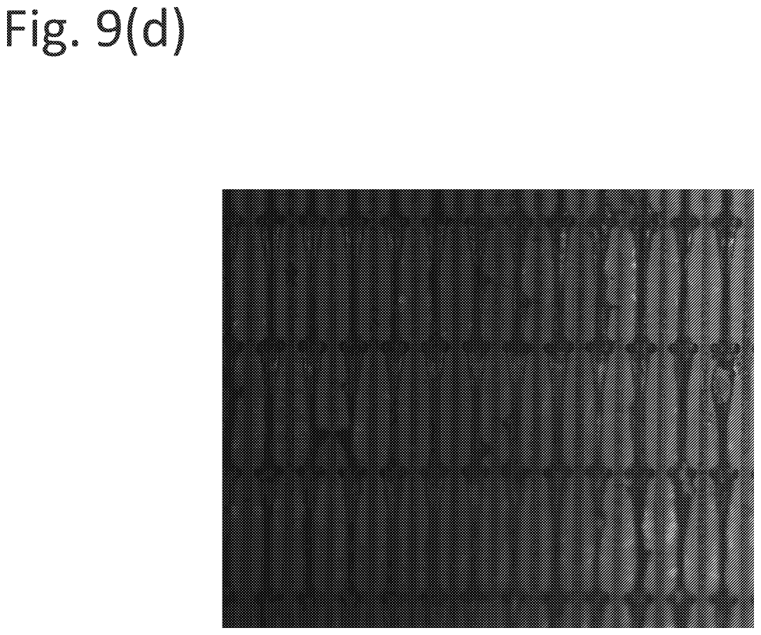

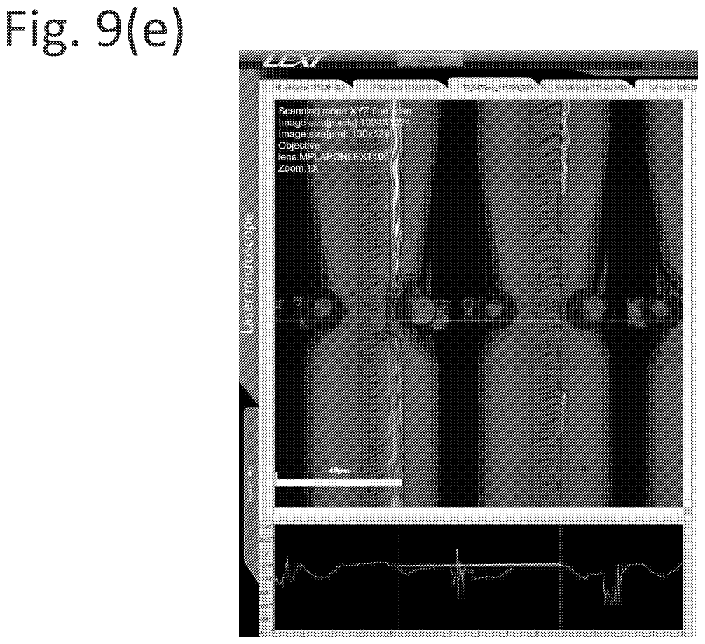

As a demonstration, due to non-availability of required nano-imprint technology, the inventors have processed a convex shape onto a growth restrict mask 104 using resist reflow methods and successfully transferred the same shape onto the interface 507 of the ELO layers 301, as shown in FIGS. 9(a), 9(b), 9(c), 9(d) and 9(e).

The graph of FIG. 9(a) is the shape of the resist pattern after reflow is applied, the image of FIG. 9(b) is a convex shape after depositing the mask 104, and the image of FIG. 9(c) is a combination of the convex patterns from the mask 104 along with open window regions 506 for ELO growth. Using MOCVD, n-GaN ELO base layers 301 were grown from the open window regions 506 and the layers 301 were removed using the method described in [Applied Physics Express 13, 041003 (2020)]. The interface 507 of the ELO layers 301 after removal is show in the image of FIG. 9(d), and a laser scan was performed to show a transferred structure in the image of FIG. 9(e).

### Definitions of Terms

### III-Nitride-Based Substrate

The III-nitride-based substrate 101 may comprise any type of III-nitride-based substrate, as long as a III-nitride-based substrate 101 enables growth of III-nitride-based semiconductor layers 301, 303, through a growth restrict mask 104, any GaN substrate 101 that is sliced on a {0001}, {11-22}, {1-100}, {20-21}, {20-2-1}, {10-11}, {10-1-1} plane, etc., or other plane, from a bulk GaN, and AlN crystal substrate.

### Foreign or Hetero-Substrate

The present invention is primarily used with foreign or hetero-substrates 101. For example, a GaN template 102 or other III-nitride-based semiconductor layer 102 may be grown on a hetero-substrate 101, such as Sapphire, Si, SiC, SiN, GaAs, Ga₂O₃, LiAlO₂, etc., prior to the growth restrict mask 104. The GaN template 102 or other III-nitride-based semiconductor layer 102 is typically grown on the hetero-substrate 101 to a thickness of about 2-6 μm, and then the growth restrict mask 104 is disposed on the GaN template 102 or another III-nitride-based semiconductor layer 102.

### Growth Restrict Mask

The growth restrict mask 104 comprises a dielectric layer, such as SiO₂, SiN, SiON, Al₂O₃, AlN, AlON, MgF, ZrO₂, TiN etc., or a refractory metal or precious metal, such as W, Mo, Ta, Nb, Rh, Ir, Ru, Os, Pt, etc. The growth restrict mask 104 may be a laminate structure selected from the above materials. It may also be a multiple-stacking layer structure chosen from the above materials.

In one embodiment, the thickness of the growth restrict mask 104 is about 0.05-3 μm. The width of the mask 104 is preferably larger than 20 μm, and more preferably, the width is larger than 40 μm. The growth restrict mask 104 is deposited by sputter, electron beam evaporation, plasma-enhanced chemical vaper deposition (PECVD), ion beam deposition (IBD), etc., but is not limited to those methods.

On an m-plane free standing GaN substrate 101, the growth restrict mask 104 comprises a plurality of opening areas 105, which are arranged in a first direction parallel to the 11-20 direction of the substrate 101 and a second direction parallel to the 0001 direction of the substrate 101, periodically at intervals extending in the second direction. The length of the opening areas 105 is, for example, 100 to 35000 μm; the width is, for example, 2 to 180 μm; and the interval of the opening areas 105 is, for example, 20 to 180 μm. The width of the opening areas 105 is typically constant in the second direction but may be changed in the second direction as necessary.

On a c-plane free standing GaN substrate 101, the opening areas 105 are arranged in a first direction parallel to the 11-20 direction of the substrate 101 and a second direction parallel to the 1-100 direction of the substrate 101.

On a semipolar (20-21) or (20-2-1) GaN substrate 101, the opening areas 105 are arranged in a direction parallel to [−1014] and [10-14], respectively.

Alternatively, a hetero substrate 101 can be used. When a c-plane GaN template 102 is grown on a c-plane Sapphire substrate 101, the opening area 105 is in the same direction as the c-plane free-standing GaN substrate 101; when an m-plane GaN template 102 is grown on an m-plane Sapphire substrate 101, the opening area 105 is same direction as the m-plane free-standing GaN substrate 101. By doing this, an m-plane cleaving plane can be used for dividing the bar of the device with the c-plane GaN template, and a c-plane cleaving plane can be used for dividing the bar of the device with the m-plane GaN template 102; which is much preferable.

### III-Nitride-Based Semiconductor Layers

The ELO III-nitride layers 301 and the III-device layers 303 can include In, Al and/or B, as well as other impurities, such as Mg, Si, Zn, O, C, H, etc.

The III-nitride-based semiconductor device layers 303 generally comprise more than two layers, including at least one layer among an n-type layer, an undoped layer and a p-type layer. The III-nitride-based semiconductor device layers 303 specifically comprise one or more of a GaN layer, an AlGaN layer, an AlGaInN layer, an InGaN layer, etc. In the case where the device 304 has a plurality of III-nitride-based semiconductor layers 303, the distance between the island-like III-nitride semiconductor layers 301, 303 adjacent to each other is generally 30 μm or less, and preferably 10 μm or less, but is not limited to these figures. In the semiconductor device 304, a number of electrodes according to the types of the semiconductor device 304 are disposed at predetermined positions.

### Semiconductor Device

The semiconductor device 304 is, for example, a Schottky diode, a light-emitting diode, a semiconductor laser, a photodiode, a transistor, etc., but is not limited to these devices 304. This invention is particularly useful for VCSELs 304. This invention is especially useful for semiconductor lasers 304 that require smooth regions for cavity formation.

### Alternative Embodiments

The present invention and the following embodiments disclose a III-nitride VCSEL 304 that incorporates a curved mirror 508 either on an n-side or p-side of the device 304. The use of the curved mirror 508 allows for the following:

1. The use of a long cavity without suffering from excessive diffraction loss. With two planar mirrors defining the cavity, the loss due to diffraction increases with cavity length [Applied Physics Express 12, 044004 (2009), Sci. Rep., 8, 10350 (2018)]. When using a curved mirror 508, the reflected light can be focused back into the aperture minimizing diffraction loss.

2. Better thermal management, increasing lifetime, output power, efficiency and reliability of the devices 304. High efficiency VCSEL 304 operation needs the gain spectrum to be well aligned to the cavity mode. As the cavity length increases, the mode spacing decreases. Thus, there is an efficient number of cavity modes to ensure good mode overlap with the gain spectrum. Additionally, tight cavity mode spacing allows for a greater tolerance of the cavity length and the location of the active region. Having a long cavity design can increase the yield during device 304 growth and fabrication.

3. It has been experimentally shown that there are many advantages of a III-nitride long cavity VCSEL where a curved mirror was employed on the back of the substrate [Applied Physics Express 12, 044004 (2009)]. However, the designs described herein remove the substrate 101 using conventional methods; also, the designs use a high crystalline quality ELO wing 302 for the resonant cavity, which increases the lifetime of the device 304. This invention avoids surface preparation in some designs that actually saves processing steps and are not effected by crystallinity of the substrate 101, even one-use bulk GaN substrates 101. This invention focuses on large scale manufacturing by using GaN templates 102 on foreign substrates 101.

In this invention, an advantage of forming the curved mirror 508 on the top or bottom eliminates substrate 101 thinning. For visible wavelength VCSELs 304, the long cavity length should be 8-30 μm considering the number of cavity modes and spacing. It is difficult to thin the substrate 101 to precisely control thickness. In this invention, using ELO provides advantages in achieving good wing 302 widths and thickness, which have advantages in increasing cavity thickness without adding threading dislocations.

Not having to thin substrate 101 also reduces process complexity and costs. Thinned substrates are susceptible to breaking in the handling process; however, the carrier substrate 501 of this invention avoids such problems.

### First Embodiment

In a first embodiment, a long cavity VCSEL 304 is fabricated on an ELO wing 302 of a hetero-substrate 101, the device 304 is lifted off, and then a curved DBR mirror 407 is fabricated in the interface 507.

A substrate 101 with a III-nitride template 102 is provided and a growth restrict mask 104, or ELO mask 104, is placed on the host substrate 101. III-nitride layers can be stripes as described in FIGS. 1(a), 1(b), 1(c) and 1(d), and 2(a), 2(b), 2(c) and 2(d). Then, n-GaN ELO layers 301 were grown from the open areas 105. A wing 302 of the ELO layers 301 with a width suitable for a long cavity VCSEL is achieved, and device layers 303 are grown, such as an InGaN containing active region, p-GaN layers, etc.

Device layers 303 are then activated, as ELO layers 301 not coalesced with the neighboring ELO layers 301. Activation of the p-GaN layers 404 is better in these devices 304 as sidewalls at the non-coalesced region provides a better passage for hydrogen diffusion. Then a hard mask, for example Ti/Au, was deposited to protect an aperture area during ion implantation for creating a current blocking region 405. After the implantation, the hard mask was removed with heated aqua regia and samples were cleaned directly prior to a tunnel junction 406 regrowth. Alternatively, one may also opt for ITO as a current spreading layer 406. A highly doped n++ GaN tunneling layer followed by an n-GaN current spreading layer 406 and an n++ GaN contacting layer 402 were grown by MOCVD. After that, the p-GaN 404 was again reactivated through the sidewalls.

Alternating pairs of SiO₂/Ta₂O₅ layers of a p-DBR mirror 407 were deposited, and a p-contact metal 409 around the DBR mirror 407 defined by lithography. A transparent carrier substrate 501 is bonded to the p-side of the device 304. Then, a laser or chemical lift-off is used to remove the host substrate 101.

The ELO mask 104 on the interface 507 is dissolved in a chemical etch, and resin disks with desired diameters are photolithographed on the interface 507 of the ELO wing 302. By heating the specimen, the disks melted into droplets. RIE can be used to transfer the surficial shape of the resin droplets onto the ELO interface 507 by removing them as sacrificial masks, which will leave a lens-shaped surface on the ELO interface 507. An n-side DBR 407, for example, Ta₂O₅/SiO₂ bilayers, was deposited to form curved mirrors 508, as shown in FIGS. 5(g) and 5(h). This design is specially dedicated for long cavity VCSELs 304, where resonant cavity lengths are more than 20 μm. Then, n-metal pads 408 were defined on the ELO interface 507 for vertical current injection. Alternatively, one may also use top side metal contacts 408 for lateral injection.

An example process includes the following steps:
1. Growing ELO III-nitride layers 301, generally more than 20 μm, on a GaN template 102 of a hetero-substrate 101. The ELO III-nitride layers 301 comprise the UID GaN layers 401.
2. Growing the following device layers 303 in order on the ELO III-nitride layers 301: n-GaN layers 402 (1000 nm thick) for cladding and n-contacting, InGaN multi quantum wells and GaN barriers as the active region 403, AlGaN electron blocking layer 405 (50 nm), p-GaN (300 nm thick) and p++GaN (10 nm thick) layers 404.
3. Performing an ion implantation to define an aperture.
4. After surface cleaning, regrowing n++ GaN layers (10 nm thick) to complete the tunnel junction 406.
5. Depositing n-GaN layers 402 (10-100 nm thick) for containing and current spreading.
6. Dry etching a mesa to define the devices 304.
7. Depositing dielectric DBR mirrors 407.
8. Depositing contacts 408, 409, and flip chip bonding/attaching to a transparent carrier 501.
9. Removing the substrate 101 thorough LLO or chemical etching.
10. Dissolving the ELO mask 104 on the ELO wing interface 507.
11. Using thermal reflow of resin, etching a curved mirror shape 508 having a curved surface 701 in the UID-GaN 301 with RIE.
12. Depositing dielectric DBR mirrors 407 over the curved surfaces 701.
13. Dry etching selective portions of the interface 507 to expose the n-GaN layer 402 outside the curved mirror 508 and deposit metal contacts 408, 409 (vertical injection case).
14. The resulting device 304 structure is shown in FIGS. 5(g) and 5(h) (lateral injection case), by following these steps, vertical injection design can be obtained.

Key advantages include the following:
Foreign substrates 101 can be used, so scaling will not be a problem.
High crystalline quality device layers 303 on the ELO III-nitride layers 301 results in less leakage, more lifetime and higher output power.
A DBR mirror 407 that is a curved mirror 508, where the curved surface 701 is the interface 507 of the ELO wing 302 on the growth restrict mask 104, and no special preparation is needed to smoothen the surface.
Laser or chemical lift-off will not damage the VCSEL 304.
The ELO wing interface 507 is covered with the ELO mask 104 during the removal process.
Alternatively, the invention can also be practiced by first removing the growth restrict mask 104, either partially or in whole, before growth of the device layers 303 to avoid any compensation effects, where exposing the open window regions 506 to the laser 505 from the host substrate 101 will not cause any damage to the device 304.

### Second Embodiment

A second embodiment is also a long cavity VCSEL 304 fabricated on ELO wing 302 of a hetero-substrate 101 and devices 304 are lifted off from the interface 507 after substrate 101 removal. The only difference is the curved mirror 508 is pre-processed either on the host substrate 101 or on the ELO mask 104. The ELO III-nitride layers 301 from the open areas 105 have the shape of the curved mirror 508, which eliminates further resin reflow fabrication steps and simplifies the process.

A host substrate 101 with a III-nitride template 102 is provided and a growth restrict mask 104, or ELO mask 104, is placed on a pre-processed curved surface 701 of the host substrate 101. The ELO III-nitride layers 301 can be stripes as described in FIGS. 1(a), 1(b), 1(c) and 1(d), and 2(a), 2(b), 2(c) and 2(d). The base n-GaN ELO layers 301 are grown from the opening areas 105. An ELO wing 302 with a width suitable for a long cavity VCSEL 304 is achieved, and then device layers 303, such as an n-GaN layer 402, InGaN containing active region 403, p-GaN layers 404, etc., are grown.

The device layers 303 are then activated. The ELO III-nitride layers 301 not coalesced with the neighboring ELO III-nitride layers 301, and thus activation of the p-GaN layers 404 is accomplished as the sidewalls at the non-coalesced region provides a better passage for hydrogen diffusion. Then, a hard mask, for example Ti/Au, is deposited to protect an aperture area during ion implantation for a current blocking region 405. After the implantation, the hard mask is removed with heated aqua regia and samples were cleaned directly prior to a tunnel junction 406 regrowth.

Alternatively, one may also opt for ITO as a current spreading layer 406. A tunnel junction 406 comprised of a highly doped n++ GaN tunneling layer followed by a n-GaN current spreading layer 402 and a n++ GaN contacting layer 402 are grown by MOCVD. After that, the p-GaN layers 404 are again reactivated through the sidewalls.

A p-side DBR mirror 407 comprised of alternating pairs of SiO₂/Ta₂O₅ bilayers is deposited, and a p-contact metal 409 around the DBR mirror 407 is defined by lithography. A transparent carrier substrate 501 is bonded to the p-side of the device 304. Then, a laser or chemical lift-off is used to remove the host substrate 101.

The ELO mask 104 on the ELO wing interface 507 is dissolved in a chemical etch, and then an n-side DBR 407 comprised of Ta₂O₅/SiO₂ bilayers is deposited on the curved shape 701 of the ELO interface 507, as shown in FIGS. 7(c) and 7(d). Specifically, FIG. 7(c) shows a top-side finished long cavity VCSEL 304 before submount 501 attachment, and FIG. 7(d) shows the final VCSEL device 304 using the curved surface 701 of the ELO interface 507. This design is specially dedicated to long cavity VCSELs 304, where resonant cavity lengths are more than 20 μm. Then, n-metal pads 408 are defined on the ELO interface 507 for vertical current injection. Alternatively, one may also use top side metal contacts 408 for lateral injection.

An example process includes the following steps:
1. Preparing a curved surface 701 on the host substrate 101 or the ELO mask 104.
2. Growing base ELO III-nitride layers 301, generally more than 20 μm, on a GaN template 102 on a hetero-substrate 101, wherein the ELO III-nitride layers 301 take on the shape of a curved surface 701. In this instance, the ELO III-nitride layers 301 are UID GaN layers 401.
3 Growing the following device layers 303 in order on the base ELO III-nitride layers 301: n-GaN layers 402 (1000 nm thick) for cladding and n-contacting, InGaN multi quantum wells and GaN barrier as an active region 403, AlGaN electron blocking layer 405 (50 nm), p-GaN (300 nm thick) and p++GaN (10 nm thick) layers 404.
4. Performing an ion implantation to define an aperture.
5. After surface cleaning, regrowing n++ GaN (10 nm thick) to complete the tunnel junction 406.
6 Depositing n-GaN layers 402 (10-100 nm thick) for containing and current spreading.
7. Dry etching a mesa to define the devices 304.
8. Depositing planar dielectric DBR mirrors 407.
9. Depositing contacts 408, 409, and flip chip bonding/attaching to a transparent carrier 501.
11. Removing the substrate 101 thorough LLO or chemical etching.
12. Dissolving the ELO mask 104 on the ELO wing interface 507.
13. Depositing dielectric DBR mirrors 407 over the curved surface 701 of the ELO wing interface 507.
14. Dry etching selective portions of the interface 507 to expose the n-GaN layers 402 outside the curved mirror 407 and deposit contacts 408, 409.
15. The resulting device 304 structure is shown in FIGS. 7(c) and 7(d) (lateral injection case), and by following these steps, vertical injection design can be obtained.

Key advantages include the following:
Foreign substrates 101 can be used, and scaling will not be a problem.
High crystalline quality device layers 303 due to the ELO III-nitride layers 301 results in less leakage, more lifetime and higher output power.
The curved surface 701 of the DBR mirror 407 is the interface 507 of the ELO wing 302 on the growth restrict mask 104, and therefore no special preparation is needed to smoothen the surface.
The curved surface 701 is fabricated on the host substrate 101 or ELO mask 104, so the interface 507 not subjected to further processing for curvature formation.
Laser or chemical lift-off does not damage the VCSEL 304.
The ELO wing interface 507 is covered with the ELO mask 104 during the removal process.

### Third Embodiment

A third embodiment is also a long cavity VCSEL 304 fabricated on ELO wing 302 of a hetero-substrate 101 and the devices 304 that are lifted off use the ELO wing interface 507 for the second DBR mirror 407. The difference is that the curved mirror 508 is processed on the p-side of the VCSEL 304. Before doing so, the base ELO III-nitride layers 301 are polished as in the Design I-C; however, the layers 301, 303 for the longer cavity are grown on the p-side of the device 304 and use the ELO wing interface 507 as the second DBR 407 after removing the host substrate 101.

The III-nitride layers 301, 303 comprising the cavity may be grown by MOCVD to have a total thickness greater than 8 μm. A tunnel junction 406, which is a highly doped p++/n++ junction, is grown on the p-side of the device 304, followed by 1-2 μm of n-GaN 402 or UID GaN 401. The top n-GaN 402 or UID-GaN 401 is processed to have a curved surface above an aperture defined as a current blocking region 405 with ion implantation. To etch the lens shape into the GaN 401, 402, the layer 401, 402 being etched must be as thick as, or thicker than, the thickness of the lens, and is often a few microns thick. The Ohmic contact 408 should be on the n-GaN 402 or the n++ GaN of the tunnel junction 406. The contact 408 on UID GaN 401 instead of lossy n-GaN 402 minimizes absorption loss in the VCSEL 304 cavity.

An example process includes the following steps:
1. Growing base ELO III-nitride layers 301, generally more than 10 μm, on a GaN template 102 of a hetero-substrate 101. The ELO III-nitride layers 301 comprise UID GaN layers 401.
2. Polishing may or may not be used to control cavity thickness.
3. The following device layers 303 are grown in order on the base ELO III-nitride layer 301: n-GaN layers 402 (1000 nm thick) for cladding and n-contacting, InGaN multi quantum wells and GaN barriers as an active region 403, AlGaN electron blocking layer 405 (50 nm), p-GaN (300 nm thick) and p++GaN (10 nm thick) layers 404.
4. Performing ion implantation to define an aperture.
5. After surface cleaning, regrowing n++ GaN (10 nm thick) to complete the tunnel junction 406.
6 Depositing n-GaN layers 402 (1000 nm thick) for containing and current spreading and UID GaN layers 401 (3 μm) for lens processing.
7. Dry etching a mesa to define the devices 304.
8. Using thermal reflow of resin, etching a lens shape having a curved surface 701 in the UID-GaN layers 401 down to the n-GaN layers 402 with RIE.
9. Depositing dielectric DBR mirrors 407 over the curved surfaces.
10. Depositing contacts 408, 409, and flip chip bonding to a carrier 501.
11. Removing the substrate 101 thorough LLO or chemical etching.
12. Dissolving the ELO mask 104 on the ELO wing interface 507.
13. Dry etching the interface 507 to expose the n-GaN layers 402 outside the aperture and deposit contacts 408, 409.
14. Depositing a planar dielectric DBR 407 on the untouched ELO wing interface 507 and the cavity is made significantly thicker.
15. The resulting device 304 structure is shown in FIGS. 6(g) and 6(h) (lateral injection case), and by following these steps, vertical injection design can be obtained.

Key advantages include the following:
Foreign substrates 101 can be used, and scaling will not be a problem.
High crystalline quality device layers 303 on the ELO III-nitride layers 301 results in less leakage, more lifetime and higher output power.
The curved surface of the DBR mirror 407 is on the p-side surface, so smoothness can be controlled epitaxially.
The flat DBR mirror 407 is fabricated on the ELO wing interface 507, and therefore both the surface preparation for both mirrors 407 is simple.
Laser or chemical lift-off will not damage the VCSEL 304.
The ELO wing interface 507 is covered with the ELO mask 104 during the removal process.

### Fourth Embodiment

In a fourth embodiment, a short cavity VCSEL 304 is fabricated on the ELO wing 302 of a hetero-substrate 101, the devices 304 are lifted off, and then the curved mirror 508 is fabricated on the ELO wing interface 507.

A substrate 101 with a III-nitride template 102 is provided and a growth restrict mask 104, or ELO mask 104, is placed on host substrate 101. The III-nitride template 102 can be stripes as described in FIGS. 1(a), 1(b), 1(c) and 1(d), and 2(a), 2(b), 2(c) and 2(d). Base ELO III-nitride layers 301 are grown from the opening areas 105, and comprise n-GaN layers 401. An ELO wing 302 with a width suitable for a long cavity VCSEL 304 is achieved, and then the remaining device layers 303 are grown, such as an InGaN containing active region 403, p-GaN layers 404, etc.

The p-GaN layers 404 are then activated. Because the ELO layers 301 are not coalesced with the neighboring ELO layers 301, activation of the p-GaN layers 404 is achieved using sidewalls at the non-coalesced region, which provides a better passage for hydrogen diffusion. Then, a hard mask, for example, Ti/Au, is deposited to protect an aperture area during ion implantation for creating a current blocking region 405. After the implantation, the hard mask is removed with heated aqua regia and samples are cleaned directly prior to a tunnel junction 406 regrowth. Alternatively, one may also opt for ITO as a current spreader 406. The tunnel junction 406 comprises a highly doped n++ GaN tunneling layer, followed by a n-GaN current spreading layer 402 and a n++ GaN contacting layer 402 grown by MOCVD. After that, the p-GaN layer 405 is again reactivated through the sidewalls.

The DBR mirror 407 comprised of alternating pairs of SiO₂/Ta₂O₅ bilayers is deposited, and a p-contact 409 around the DBR mirror 407 is defined by lithography. A transparent carrier substrate 501 is bonded to p-side of the device 304. Then, a laser or chemical lift-off is used to remove the host substrate 101.

The ELO mask 104 on the ELO wing interface 507 is dissolved in a chemical etch, and then the ELO III-nitride layers 301 are thinned to a desired resonant cavity length for achieving the short cavity design. An n-side DBR 407 comprised of Ta₂O₅/SiO₂ bilayers is deposited, as shown in FIGS. 5(i) and 5(j). This design is specially useful for short cavity VCSELs 304. Then, n-contacts 408 are defined on the ELO wing interface 507 for vertical current injection. Alternatively, one may also use top side contacts 408 for lateral injection.

An example process includes the following steps:
1. Preparing an ELO mask 104 with a planar surface on the host substrate 101.
2. Growing base ELO III-nitride layers 301 generally more than 20 μm, on a GaN template 102 on the host substrate 101. The ELO III-nitride layers 301 comprise UID-GaN layers 401.
3. Growing the following device layers 303 in order on the ELO III-nitride layers 301: n-GaN layers 402 (1000 nm thick) for cladding and n-contacting, InGaN multi quantum wells and GaN barriers as an active region 403, AlGaN electron blocking layer 405 (50 nm), p-GaN (300 nm thick) and p++GaN (10 nm thick) layers 404.
4. Performing an ion implantation to define an aperture.
5. After surface cleaning, regrowing n++ GaN (10 nm thick) to complete the tunnel junction 406.
6 Depositing n-GaN layers 402 (10-100 nm thick) for containing and current spreading.
7. Dry etching a mesa to define the devices 304.
8. Depositing planar dielectric DBR mirrors 407.
9. Depositing contacts 408, 409, and flip chip bonding/attaching to a transparent carrier 501.
11. Removing the substrate 101 through LLO or chemical etching.
12. Dissolving the ELO mask 104 on the ELO wing interface 507.
13. Thinning the ELO wing interface 507 to reach a designed short cavity thickness.
14. Depositing dielectric DBR mirrors 407 over the thinned surface on the ELO wing 302.
15. Dry etching selective portions of the interface 507 to expose the n-GaN layers 402 outside the aperture and deposit contacts 408, 409.
16. The resulting device 304 structure is shown in FIGS. 5(i) and 5(j) (lateral injection case), and by following these steps, lateral injection design can be obtained.

Key advantages include the following:
Foreign substrates 101 can be used, and scaling will not be a problem.
High crystalline quality device layers 303 due to the ELO III-nitride layers 301 results in less leakage, more lifetime and higher output power.
Thinning the ELO wing interface 507 by bonding the VCSEL device 304 to a carrier 501.
Laser or chemical lift-off does not damage the VCSEL 304.
The ELO wing interface 507 is covered with the ELO mask 104 during the removal process.

### Fifth Embodiment

In a fifth embodiment, a short cavity VCSEL 304 is fabricated on the ELO wing 302 of a hetero-substrate 101, the devices 304 are lifted off, and then a DBR mirror 407 is placed on the ELO wing interface 507.

A substrate 101 with a III-nitride template 102 is provided and a growth restrict mask 104, or ELO mask 104, is placed on the host substrate 101. The III-nitride template 102 can be stripes as described in FIGS. 1(a), 1(b), 1(c) and 1(d), and 2(a), 2(b), 2(c), and 2(d). The base ELO III-nitride layers 301 are grown from the opening areas 105 and comprise n-GaN layers 402. An ELO wing 302 with a width suitable for a long cavity VCSEL 304 is achieved, and device layers 303 are grown, such as an InGaN containing active region 403, p-GaN layers 404, etc., as shown in FIGS. 6(a) and 6(b).

The device layers 303 are activated. Because the ELO III-nitride layers 301 are not coalesced with neighboring ELO III-nitride layers 301, activation of the p-GaN layers 404 is easier as sidewalls at the non-coalesced region provide a better passage for hydrogen diffusion. Then, a hard mask, for example Ti/Au, is deposited to protect an aperture area during ion implantation for creating a current blocking region 405. After the implantation, the hard mask is removed with heated aqua regia and samples are cleaned directly prior to a tunnel junction 406 regrowth.

Alternatively, one may also opt for ITO as a current spreader 406. The tunnel junction 406 comprises a highly doped n++ GaN tunneling layer, followed by an n-GaN current spreading layer 402 and a n++ GaN contacting layer 402 grown by MOCVD. After that, the p-GaN layers 404 are again reactivated through the sidewalls.

A DBR mirror 407 comprised of alternating pairs of SiO₂/Ta₂O₅ bilayers is deposited, and a p-contact 409 around the DBR mirror 407 is defined by lithography. A transparent carrier substrate 501 is bonded to p-side of the device 304. Then, a laser or chemical lift-off is used to remove the host substrate 101.

The ELO mask 104 on the ELO wing interface 507 is dissolved in a chemical etch, and then an n-side DBR mirror 407 comprised of Ta₂O₅/SiO₂ bilayers is deposited to form a second DBR mirror 407 of the VCSEL 304, as shown in FIGS. 6(e) and 6(f). This design is especially dedicated for short cavity VCSELs 304. Then, n-contacts 408 are defined on the ELO wing interface 507 for vertical current injection. Alternatively, one may also use top side n-contacts 408 for lateral injection.

An example process includes the following steps:
1. Preparing an ELO mask 104 with a planar surface on the host substrate 101.
2. Growing ELO III-nitride layers 301, generally more than 20 μm, on a GaN template 102 of the substrate 101. The ELO III-nitride layers 301 comprise UID GaN layers 401.
3. Thinning the ELO III-nitride layers 301 from the top of the surface (in this design, the thinning is performed with the host substrate 101 still attached).
4. Growing the following device layers 303 in order on the ELO III-nitride layers 301: n-GaN layers 402 (1000 nm thick) for cladding and n-contacting, InGaN multi quantum wells and GaN barriers as an active region 403, AlGaN electron blocking layer 405 (50 nm), p-GaN (300 nm thick) and p++GaN (10 nm thick) layers 404.
5. Performing an ion implantation to define an aperture.
6. After surface cleaning, regrowing n++ GaN (10 nm thick) to complete a tunnel junction 406.
7. Depositing n-GaN layers 402 (10-100 nm thick) for containing and current spreading.
8. Dry etching an mesa to define the devices 304.
9. Depositing planar dielectric DBR mirrors 407.
10. Depositing contacts 408, 409, and flip chip bonding/attaching to a carrier 501.
11. Removing the substrate 101 thorough LLO or chemical etching.
12. Dissolving the ELO mask 104 on the ELO wing interface 507.
13. Depositing dielectric DBR mirrors 407 over the ELO wing interface 507.
14. Dry etching the interface 507 to expose the n-GaN layers 402 outside the aperture and deposit contacts 408, 409.
15. The resulting device 304 structure is shown in FIGS. 6(e) and 6(f) (lateral injection case), and by following these steps, lateral injection design can be obtained.

Key advantages include the following:
Foreign substrates 101 can be used, and scaling will not be a problem.
High crystalline quality device layers 303 due to the ELO III-nitride layers 301 results in less leakage, more lifetime and higher output power.
Thinning is performed on the ELO layers 301 with the host substrate 101 still attached.
Laser or chemical lift-off does not damage the device 304.
The ELO wing interface 507 is covered with the ELO mask 104 during the removal process.

### Process Steps

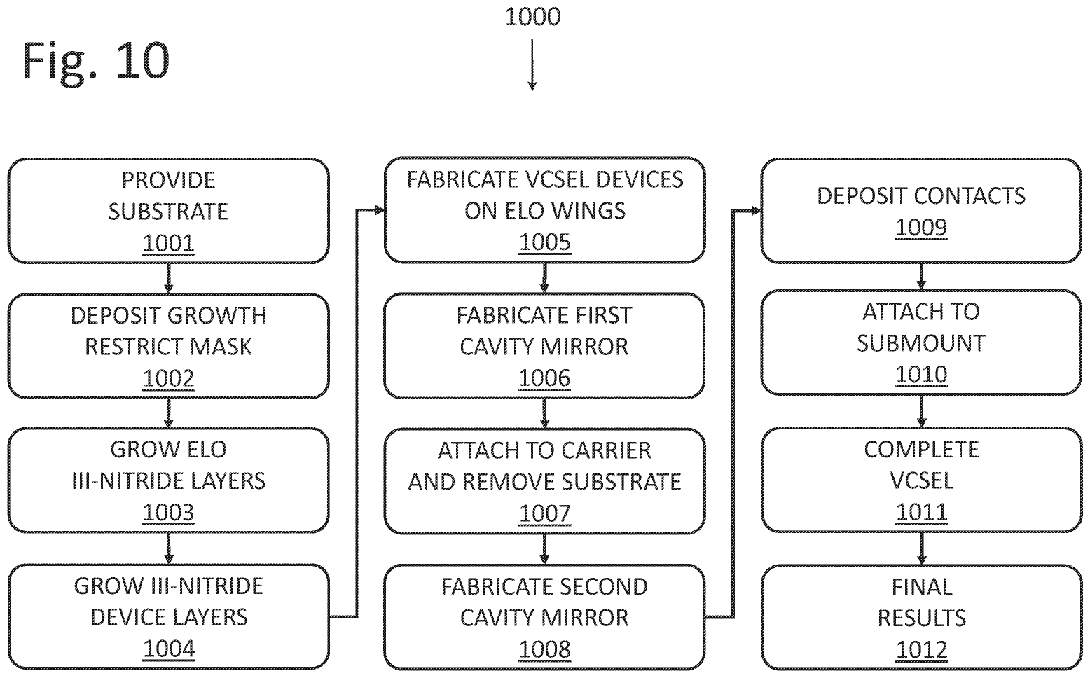

FIG. 10 is a flowchart illustrating a method 1000 for fabricating semiconducting devices according to this invention. Specifically, FIG. 10 illustrates a method 1000 for fabricating VCSELs 304.

Block 1001 represents the step of providing a host substrate 101. In this step, the host substrate 101 comprises a III-nitride substrate 101 or a foreign substrate 101 with a III-nitride template 102 deposited thereon. The III-nitride template 102 is comprised of one or more selective growth assisting portions formed on the host substrate.

Block 1002 represents the step of depositing a growth restrict mask 104 on or above the host substrate 101, wherein the growth restrict mask 104 may be patterned. Specifically, the growth restrict mask 104 is deposited directly on the substrate 101, or is deposited directly on the III-nitride template 102 deposited on the substrate 101. The use of the III-nitride template 102 may result in one or more non-growth assisting portions of the host substrate 101 being in direct contact with a bottom surface of the growth restrict mask 104.

The growth restrict mask 104 is typically an insulator film, for example, SiO₂, SiN, SiON, TiN, etc., deposited, for example, by plasma chemical vapor deposition (CVD), sputter, ion beam deposition (IBD), etc.

The growth restrict mask 104 is fabricated to have the patterned surface that is transferred to the interface 507 of the ELO III-nitride layers 301. Alternatively, the host substrate 101 is fabricated to have the patterned surface that is transferred to the growth restrict mask 104 and then to the interface 507 of the ELO III-nitride layers 301.

Block 1003 represents the step of forming one or more ELO III-nitride layers 301 on the growth restrict mask 104, first from opening areas 105 in the growth restrict mask 104 and then laterally over the growth restrict mask 104, wherein the ELO III-nitride layers 301 may or may not coalesce with adjacent or neighboring ELO III-nitride layers 301. The ELO III-nitride layers 301 may comprise UID GaN layers 401 and/or n-type GaN layers 402.

Block 1004 represents the step of forming at least one VCSEL 304 on the ELO III-nitride layers 301, wherein the VCSEL 304 is comprised of III-device layers 303 including at least a III-nitride active region 403 between n-type III-nitride layers 402 and p-type III-nitride layers 404 grown on or above the ELO III-nitride layers 301, and the ELO III-nitride layers 301 and III-device layers 303 together comprise island-like III-nitride semiconductor layers 301, 303.

In one embodiment, the III-device layers 303 may include: UID GaN layers 401, n-GaN layers 402 for cladding and n-contacting, InGaN multi quantum wells and GaN barriers as an active region 403, p-GaN and p++GaN layers 404, electron blocking layers 405, tunnel junction 406 or transparent conducting layers 406.

Preferably, the III-device layers 303 are grown on wings 302 of the ELO III-nitride layers 301. Moreover, a light emitting aperture of the VCSEL 304 is made on the wing 302 of the ELO III-nitride layers 301. In situations where multiple VCSELs 304 may be fabricated, the III-nitride device layers 303 of first and second VCSELs 304 are fabricated on adjacent wings 302 of the ELO III-nitride layers 301.

Block 1005 represents the step of fabricating a light emitting device 304, such as a VCSEL 304, on the wing 302 of the ELO III-nitride layers 301, that is mostly covered by a flat surface region, by conventional lithography methods. This step may include performing an ion implantation to define an aperture, etching a mesa to define the devices 304, etc.

Block 1006 represents the step of placing at least one first DBR mirror 407 defining a resonant cavity of the VCSEL 304 on or above the III-nitride device layers 303. Specifically, the DBR mirror 407 defining the resonant cavity of the VCSEL 304 is placed on a p-side of the III-nitride device layers 303.

The DBR mirror 407 may be formed on or above the p-type III-nitride layers 404, such that the p-type III-nitride layers 404 are between the III-nitride active region 403 and the DBR mirror 407.

The VCSEL 304 may further comprise one or more tunnel junction 406 layers on the p-type III-nitride layers 404, and the DBR mirror 407 is formed below the tunnel junction 406 layers, such that the ELO III-nitride layers 301 are between the DBR mirror 407 and the tunnel junction 406 layers.

The VCSEL 304 may further comprise one or more tunnel junction 406 layers on the p-type III-nitride layers 404, and the DBR mirror 407 is formed on or above the tunnel junction 406 layers, such that the tunnel junction 406 layers are between the DBR mirror 407 and the p-type III-nitride layers 404.

This step may include, after surface cleaning, regrowing n++ GaN layers to complete the tunnel junction 406, depositing additional n-type GaN layers 402 on or above the tunnel junction 406 for current spreading, etc. The additional n-type III-nitride layers 402 have a curvature shape for a DBR mirror 407.

Block 1007 represents the step of attaching the device 304 structure to a carrier 501, and then removing the ELO III-nitride layers 301 and the VCSEL 304 from the host substrate 101 to expose an interface 507 of the ELO III-nitride layers 301.

Specifically, the p-side of the III-nitride device layers 303 with the DBR 407 is attached to the carrier 501 or a submount and then LLO or chemical etching is used to lift-off the ELO III-nitride layers 301 and the III-nitride device layers 303 from the host substrate 101. The laser 505 is used at an open window region 506 of a wing 302 of the ELO III-nitride layers 301 to lift-off the ELO III-nitride layers 301 and the III-nitride device layers 303 from the host substrate 101, so that the III-nitride device layers 303 grown on the ELO III-nitride layers 301 are not damaged.

This step includes dissolving the growth restrict mask 104 on the ELO wing interface 507, and using a thermal reflow of resin to etch a curved mirror 508 shape having a curved surface 701 in the UID-GaN layers 401 using RIE.

Block 1008 represents the step of placing at least one second DBR mirror 407 defining a resonant cavity of the VCSEL 304 on the interface 507 of the ELO III-nitride layers 301. In one embodiment, the DBR mirror 407 is placed on a wing 302 of the ELO III-nitride layers.

The interface 507 of the ELO III-nitride layers 301 may have a patterned surface for the DBR mirror 407, wherein the patterned surface comprises a curvature shape 701 for the DBR mirror 407.

In an embodiment where the VCSEL 304 is comprised of first and second DBR mirrors 407, the first DBR 407 mirror may comprise a flat DBR mirror 407, the second DBR mirror 407 may comprise a flat DBR mirror 407 or a curved DBR mirror 407, and the III-nitride active region 403 is positioned between the first and second DBR mirrors 407.

The ELO III-nitride layers 301 may comprise more than 50% of the resonant cavity between the first and second DBRs 407, wherein the ELO III-nitride layers 301 comprise the UID GaN layers 401 or the n-type GaN layers 402. The interface 507 of the ELO III-nitride layers 301 is on an n-side of the VCSEL 304.

In one embodiment, a total cavity length of the resonant cavity is more than 8 μm; alternatively, the host substrate 101 or the interface 507 of the ELO III-nitride layers 107 is thinned to reduce a total cavity length of the resonant cavity to less than 8 μm.

Block 1009 represents the step of depositing contacts 408, 409 for the VCSEL 304. In one embodiment, where the VCSEL 304 includes a tunnel junction 406, the contacts may comprise n-contacts 408; in other embodiments, the contacts may comprise both n-contacts 408 and p-contacts 409.

This step may include the etching of selective portions of the interface 507 to expose the n-GaN layers 402 for the deposition of metal n-contacts 408.

This step also may include forming a lateral injection configuration or a vertical injection configuration for injecting current into the devices 304, including depositing n-contacts 408 and p-contacts 409 on the devices 304. These configurations allow each device 304 of a bar of devices 304 to be addressed separately or to be addressed together with other devices 304.

Block 1010 represents the step of transferring the devices 304 onto a submount, or other external carrier. In one embodiment, this step includes flip-chip bonding of the devices 304 including the island-like III-nitride semiconductor layers 301, 303 to a transparent submount, or other external carrier.

Block 1011 represents the step of completing the fabrication of the VCSELs 304. This step may include packaging the VCSELs 304, etc.

Block 1012 represents the final result of the method, namely, the completed devices 304, and any application including the completed devices 304.

### REFERENCES

The following references are incorporated by reference herein:
1. US Patent Application Publication No. 2017/0092810, filed on Jun. 11, 2014, by Raring et al., published on Mar. 30, 2017, and entitled “Surface morphology of non-polar gallium nitride containing substrates.”
2. Applied Physics Express 13, 041003 (2020).
3. Applied Physics Express 12, 044004 (2009).
4. Sci. Rep., 8, 10350 (2018).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto

What is claimed is:

1. A method, comprising:
providing a host substrate;
depositing a growth restrict mask on the host substrate;
forming one or more epitaxial lateral overgrowth (ELO) III-nitride layers on the growth restrict mask;
forming at least one vertical cavity surface emitting laser (VCSEL) on the ELO III-nitride layers, wherein the VCSEL is comprised of III-nitride device layers including at least a III-nitride active region between n-type III-nitride layers and p-type III-nitride layers;
removing the ELO III-nitride layers and the VCSEL from the host substrate to expose an interface of the ELO III-nitride layers; and
placing at least one distributed Bragg reflector (DBR) mirror defining a resonant cavity of the VCSEL on the interface of the ELO III-nitride layers.

2. The method of claim 1, wherein selective growth assisting portions are formed on the host substrate

3. The method of claim 1, wherein non-growth assisting portions of the host substrate are in direct contact with a bottom surface of the growth restrict mask.

4. The method of claim 1, wherein the DBR mirror is placed on a wing of the ELO III-nitride layers.

5. The method of claim 1, wherein the interface of the ELO III-nitride layers has a patterned surface for the DBR mirror.

6. The method of claim 5, wherein the patterned surface comprises a curvature shape for the DBR mirror.

7. The method of claim 5, wherein the growth restrict mask is fabricated to have the patterned surface that is transferred to the interface of the ELO III-nitride layers.

8. The method of claim 5, wherein the host substrate is fabricated to have the patterned surface that is transferred to the interface of the ELO III-nitride layers.

9. The method of claim 1, wherein the VCSEL further comprises one or more tunnel junction layers on the p-type III-nitride layers, and the DBR mirror is formed below the tunnel junction layers, such that the ELO III-nitride layers are between the DBR mirror and the tunnel junction layers.

10. The method of claim 9, wherein the DBR mirror is formed on or above the p-type III-nitride layers, such that the p-type III-nitride layers are between the III-nitride active region and the DBR mirror.

11. The method of claim 1, wherein the VCSEL further comprises one or more tunnel junction layers on the p-type III-nitride layers, and the DBR mirror is formed on or above the tunnel junction layers, such that the tunnel junction layers are between the DBR mirror and the p-type III-nitride layers.

12. The method of claim 11, wherein the VCSEL further comprises additional n-type III-nitride layers on or above the tunnel junction layers, and the additional n-type III-nitride layers have a curvature shape forming the DBR mirror.

13. The method of claim 1, wherein:
the at least one DBR mirror comprises first and second DBR mirrors,
the first DBR mirror comprises a flat DBR mirror,
the second DBR mirror comprises a flat DBR mirror or a curved DBR mirror, and
the III-nitride active region is positioned between the first and second DBR mirrors.

14. The method of claim 1, wherein the ELO III-nitride layers comprise more than 50% of the resonant cavity, and the ELO III-nitride layers comprise GaN, unintentionally-doped GaN, or n-type GaN.

15. The method of claim 1, wherein a total cavity length of the resonant cavity is more than 8 μm.

16. The method of claim 1, wherein the interface of the ELO III-nitride layers is thinned to reduce a total cavity length of the resonant cavity to less than 8 μm.

17. The method of claim 1, wherein the host substrate is thinned to reduce a total cavity length of the resonant cavity to less than 8 μm.

18. The method of claim 1, wherein the interface of the ELO III-nitride layers is on an n-side of the VCSEL.

19. The method of claim 18, wherein the DBR mirror defining the resonant cavity of the VCSEL is placed on a p-side of the III-nitride device layers.

20. The method of claim 19, wherein the p-side of the III-nitride device layers with the DBR is attached to a submount and then a laser or chemical etchant is used to lift-off the III-nitride device layers from the host substrate.

21. The method of claim 20, wherein the laser is used at an open window region of a wing of the ELO III-nitride layers to lift-off the III-nitride device layers from the host substrate, so that the III-nitride device layers grown on the ELO III-nitride layers are not damaged.

22. The method of claim 1, wherein the device layers of the VCSEL are fabricated on a wing of the ELO III-nitride layers.

23. The method of claim 22, wherein a light emitting aperture of the VCSEL is made on the wing of the ELO III-nitride layers.

24. The method of claim 1, wherein the at least one VCSEL comprises first and second VCSELs, and the III-nitride device layers of the first and second VCSEL are fabricated on adjacent wings of the ELO III-nitride layers.

25. A vertical cavity surface emitting laser (VCSEL) fabricated by the method of claim 1.

26. A device, comprising:
a host substrate;
a growth restrict mask deposited on the host substrate;
one or more epitaxial lateral overgrowth (ELO) III-nitride layers formed on the growth restrict mask;
at least one vertical cavity surface emitting laser (VCSEL) formed on the ELO III-nitride layers, wherein the VCSEL is comprised of III-nitride device layers including at least a III-nitride active region between n-type III-nitride layers and p-type III-nitride layers;
wherein the ELO III-nitride layers and the VCSEL are removed from the host substrate to expose an interface of the ELO III-nitride layers; and
wherein at least one distributed Bragg reflector (DBR) mirror defining a resonant cavity of the VCSEL is placed on the interface of the ELO II-nitride layers.
